(19) United States
(12) Patent Application Publication
(10) Pub. No.: US 2022/0404526 A1
(43) Pub. Date: Dec. 22, 2022

(54) TRANSFER FILM, BASE MATERIAL FOR DISPLAY PANEL, MANUFACTURING METHOD OF BASE MATERIAL FOR DISPLAY PANEL, AND DISPLAY PANEL

(71) Applicant: FUJIFILM Corporation, Tokyo (JP)

(72) Inventors: Hisashi Onitsuka, Shizuoka (JP); Yasuhiro Kawatani, Shizuoka (JP); Kei Shimotani, Shizuoka (JP)

(73) Assignee: FUJIFILM Corporation, Tokyo (JP)

(21) Appl. No.: 17/826,819

(22) Filed: May 27, 2022

(30) Foreign Application Priority Data
May 31, 2021 (JP) 2021-091721

(51) Int. Cl. G02B 1/04; G02B 1/10; H01L 33/58; G02B 5/20; C08J 5/18; C09D 167/02; C09D 5/00

(52) U.S. Cl. CPC G02B 1/04; G02B 1/10; H01L 33/58; G02B 5/20; C08J 5/18; C09D 167/025; C09D 5/00; G02B 2207/101; C08J 2367/02

(57) ABSTRACT

Provided are (1) a transfer film which is used for manufacturing a base material for a display panel, the transfer film including a temporary support and a transfer layer including a photosensitive layer, in which a softening temperature of the photosensitive layer after exposure is 300° C. or higher; (2) a transfer film which is used for manufacturing a base material for a display panel, the transfer film including a temporary support and a transfer layer including a photosensitive layer, in which a transmittance of the photosensitive layer at a photosensitive wavelength is 30% or more; and (3) applications thereof.

### CROSS-REFERENCE TO RELATED APPLICATIONS

This application claims priority from Japanese Patent Application No. 2021-091721, filed May 31, 2021, the disclosure of which is incorporated herein by reference in its entirety.

### BACKGROUND OF THE INVENTION

### 1. Field of the Invention

The present disclosure relates to a transfer film, a base material for a display panel, a manufacturing method of a base material for a display panel, and a display panel.

### 2. Description of the Related Art

In a display panel of a display device such as an LED display, a technique for forming a pixel in a region surrounded by a partition wall has been known. The LED is an abbreviation for “Light Emitting Diode”. For example, in a micro LED display panel including a color conversion device, which is disclosed in JP2020-204759A, a light emitting layer is surrounded by a first partition wall and a second partition wall. Each of the first partition wall and the second partition wall is formed by applying a photosensitive resin to form a coating film, and then performing exposure and development. That is, the partition walls in JP2020-204759A are formed by photolithography.

In the photolithography disclosed in JP2020-204759A, a method of applying the photosensitive resin is used, but in general photolithography, a method of using a transfer film is also used. For example, JP2021-042369A discloses a dry film including a resin layer composed of a curable resin composition which includes an amidoimide resin, a compound having an ethylenically double bond, and a photopolymerization initiator.

### SUMMARY OF THE INVENTION

In the display panel in the related art, problems such as collapse and deformation of the partition wall separating the pixel may occur. The collapse and deformation of the partition wall are likely to occur in a manufacturing process such as a heating step and a step of forming the pixel in a space defined by the partition wall. Examples of the deformation of the partition wall include meandering of the partition wall. Furthermore, the above-described problems are more likely to occur as an aspect ratio of the partition wall increases. The aspect ratio of the partition wall indicates a ratio of a height of the partition wall to a width of the partition wall. The “aspect ratio increases” includes, as compared to a standard, (1) the width is smaller and the height is larger, (2) the width is constant and the height is larger, and (3) the height is constant, and the width is smaller. The demand for the partition wall having a high aspect ratio is expected to increase with miniaturization of the pixel in applications such as a micro LED display.

By applying a transfer film to a manufacturing method of a base material for a display panel, particularly a manufacturing method of a base material for a display panel, which includes a partition wall separating pixels from each other, it is considered that the transfer film can contribute to improvement of productivity, reduction of man-hours, and increase of the height of the partition wall. In the present disclosure, the “base material for a display panel” means an article for constituting a display panel. In the present disclosure, depending on an aspect, the term “base material for a display panel” may be used not only for a material of the display panel, but also for a part of the display panel. On the other hand, as shown in JP2020-204759A, since the partition wall separating the pixels from each other is generally manufactured by applying the photosensitive resin, there is a demand for a transfer film suitable for manufacturing the base material for a display panel.

An object of one embodiment of the present disclosure is to provide a base material for a display panel, including a partition wall which is less likely to collapse and deform.

An object of another embodiment of the present disclosure is to provide a manufacturing method of base material for a display panel, including a partition wall which is less likely to collapse and deform.

An object of another embodiment of the present disclosure is to provide a display panel including a partition wall which is less likely to collapse and deform.

An object of another embodiment of the present disclosure is to provide a transfer film that a pattern which is less likely to collapse and deform is formed and that is used in the manufacturing of the base material for a display panel.

An object of another embodiment of the present disclosure is to provide a transfer film that a pattern having a high aspect ratio is formed and that is used in the manufacturing of the base material for a display panel.

The present disclosure includes the following aspects.

<1> A base material for a display panel, comprising:

a partition wall separating pixels,

in which the partition wall is a composition including an organic resin,

a width of the partition wall is 1 μm or more,

a ratio of a height of the partition wall to the width of the partition wall is 1 or more, and

a softening temperature of the partition wall is 300° C. or higher.

<2> The base material for a display panel according to <1>,

in which an elastic modulus of the partition wall is 4 GPa or more.

<3> The base material for a display panel according to <1> or <2>,

in which a double bond value of the partition wall is 2.0 mmol/g or less.

<4> The base material for a display panel according to any one of <1> to <3>,

in which a double bond value of the partition wall is 0.01 mmol/g or more.

<5> The base material for a display panel according to any one of <1> to <4>,

in which a solubility of the partition wall in propylene glycol monomethyl ether acetate is 0.1 g/L or less.

<6> The base material for a display panel according to any one of <1> to <5>,

in which the composition includes a nitrogen-containing compound.

<7> The base material for a display panel according to any one of <1> to <6>,

in which the composition includes a chlorine compound.

<8> The base material for a display panel according to any one of <1> to <7>,

in which the composition includes at least one compound selected from the group consisting of a compound having an oxime ester structure, a compound having an α-hydroxyalkylphenone structure, a compound having an acylphosphine oxide structure, and a compound having a triarylimidazole structure.

<9> The base material for a display panel according to any one of <1> to <8>,

in which the composition includes at least one compound selected from the group consisting of a dialkylaminobenzophenone compound, a pyrazoline compound, an anthracene compound, a coumarin compound, a xanthone compound, a thioxanthone compound, an acridone compound, an oxazole compound, a benzoxazole compound, a thiazole compound, a benzothiazole compound, a triazole compound, stilbene compound, a triazine compound, a thiophene compound, a naphthalimide compound, a triarylamine compound, and an aminoacridine compound.

<10> The base material for a display panel according to any one of <1> to <9>,

in which the composition includes a compound having at least one polymerizable group selected from the group consisting of a vinyl group, an acryloyl group, a methacryloyl group, a styryl group, and a maleimide group.

<11> The base material for a display panel according to any one of <1> to <10>,

in which the composition includes an ultraviolet absorber.

<12> The base material for a display panel according to any one of <1> to <11>,

in which the composition includes a pigment.

<13> The base material for a display panel according to any one of <1> to <12>,

in which an optical density of the partition wall is 2.5 or more.

<14> The base material for a display panel according to any one of <1> to <13>, further comprising:

a light shielding film with which at least a part of a surface of the partition wall is coated.

<15> The base material for a display panel according to <14>,

in which a thickness of the light shielding film is 50 nm or more.

<16> A display panel comprising:

the base material for a display panel according to any one of <1> to <15>.

<17> A manufacturing method of a base material for a display panel, the base material including a partition wall separating pixels, in which the partition wall is a composition including an organic resin, a width of the partition wall is 1 μm or more, a ratio of a height of the partition wall to the width of the partition wall is 1 or more, and a softening temperature of the partition wall is 300° C. or higher, the manufacturing method comprising:

preparing a transfer film which includes a temporary support and a transfer layer including a photosensitive layer;

bonding the transfer film to a substrate to arrange the transfer layer and the temporary support in this order on the substrate;

performing a pattern exposure to the transfer layer; and

performing a development treatment to the transfer layer to form a pattern constituting the partition wall.

<18> The manufacturing method of a base material for a display panel according to <17>, further comprising:

peeling off the temporary support arranged on the substrate.

<19> The manufacturing method of a base material for a display panel according to <17> or <18>, further comprising:

heating the partition wall.

<20> The manufacturing method of a base material for a display panel according to any one of <17> to <19>, further comprising:

coating at least a part of a surface of the partition wall with a light shielding film.

<21> A transfer film which is used for manufacturing a base material for a display panel, the transfer film comprising:

a temporary support; and

a transfer layer including a photosensitive layer,

in which a softening temperature of the photosensitive layer after exposure is 300° C. or higher.

<22> A transfer film which is used for manufacturing a base material for a display panel, the transfer film comprising:

a temporary support; and

a transfer layer including a photosensitive layer,

in which a transmittance of the photosensitive layer at a photosensitive wavelength is 30% or more.

<23> The transfer film according to <21> or <22>,

in which the photosensitive layer includes a crosslinking compound.

<24> The transfer film according to any one of <21> to <23>,

in which the photosensitive layer includes at least one photopolymerization initiator selected from the group consisting of a compound having an oxime ester structure, a compound having an α-hydroxyalkylphenone structure, a compound having an acylphosphine oxide structure, and a compound having a triarylimidazole structure.

<25> The transfer film according to any one of <21> to <24>,

in which the photosensitive layer includes at least one sensitizer selected from the group consisting of a dialkylaminobenzophenone compound, a pyrazoline compound, an anthracene compound, a coumarin compound, a xanthone compound, a thioxanthone compound, an acridone compound, an oxazole compound, a benzoxazole compound, a thiazole compound, a benzothiazole compound, a triazole compound, stilbene compound, a triazine compound, a thiophene compound, a naphthalimide compound, a triarylamine compound, and an aminoacridine compound.

<26> The transfer film according to any one of <21> to <25>,

in which the photosensitive layer includes a polymerizable compound having at least one polymerizable group selected from the group consisting of a vinyl group, an acryloyl group, a methacryloyl group, a styryl group, and a maleimide group.

<27> The transfer film according to any one of <21> to <26>,

in which the photosensitive layer includes an ultraviolet absorber.

<28> The transfer film according to any one of <21> to <27>,

in which the photosensitive layer includes a pigment.

According to one embodiment of the present disclosure, a base material for a display panel, including a partition wall which is less likely to collapse and deform, is provided.

According to another embodiment of the present disclosure, a manufacturing method of base material for a display panel, including a partition wall which is less likely to collapse and deform, is provided.

According to another embodiment of the present disclosure, a display panel including a partition wall which is less likely to collapse and deform is provided.

According to another embodiment of the present disclosure, a transfer film that a pattern which is less likely to collapse and deform is formed and that is used in the manufacturing of the base material for a display panel is provided.

According to another embodiment of the present disclosure, a transfer film that a pattern having a high aspect ratio is formed and that is used in the manufacturing of the base material for a display panel is provided.

### BRIEF DESCRIPTION OF THE DRAWINGS

FIG. 1 is a schematic enlarged cross-sectional view showing a display panel according to an embodiment.

FIGS. 2A to 2D are schematic enlarged cross-sectional views showing a manufacturing method of the display panel shown in FIG. 1.

### DESCRIPTION OF THE PREFERRED EMBODIMENTS

Hereinafter, embodiments of the present disclosure will be described in detail. The present disclosure is not limited to the following embodiments. The following embodiments may be modified as appropriate within the scope of the purposes of the present disclosure.

In a case where the embodiments of the present disclosure are described with reference to the drawings, the description of overlapping constituent elements and reference numerals may be omitted in the drawings. The constituent elements indicated by the same reference numeral in the drawings mean the same constituent element. A dimensional ratio in the drawings does not necessarily represent the actual dimensional ratio.

In the present disclosure, the numerical ranges shown using “to” indicate ranges including the numerical values described before and after “to” as the lower limit value and the upper limit value. In the numerical range described stepwise in the present disclosure, the upper limit value or the lower limit value described in a certain numerical range may be replaced with the upper limit value or the lower limit value of another numerical range described stepwise. In addition, regarding the numerical range described in the present disclosure, an upper limit value or a lower limit value described in a numerical value may be replaced with a value described in Examples.

In the present disclosure, the term “step” includes not only an independent step but also a step that cannot be clearly distinguished from other steps, as long as the intended purpose of the step is achieved.

In the present disclosure, “transparent” means that an average transmittance of visible light having a wavelength of 400 nm to 700 nm is 80% or more, preferably 90% or more.

In the present disclosure, the average transmittance of visible light is a value measured by using a spectrophotometer, and for example, can be measured by using a spectrophotometer U-3310 manufactured by Hitachi, Ltd.

In the present disclosure, unless otherwise specified, a weight-average molecular weight (Mw) and a number average molecular weight (Mn) are values obtained by a gel permeation chromatography (GPC) analysis apparatus and converted using polystyrene as a standard substance, with TSKgel GMHxL, TSKgel G4000HxL, or TSKgel G2000HxL (all product names manufactured by Tosoh Corporation) as a column, tetrahydrofuran (THF) as an eluent, and a differential refractometer as a detector.

In the present disclosure, unless otherwise specified, a molecular weight of a compound having a molecular weight distribution is the weight-average molecular weight (Mw).

In the present disclosure, unless otherwise specified, a content of metal elements is a value measured by using an inductively coupled plasma (ICP) spectroscopic analysis apparatus.

In the present disclosure, unless otherwise specified, a refractive index is a value measured by using an ellipsometer at a wavelength of 550 nm.

In the present disclosure, unless otherwise specified, a hue is a value measured by using a colorimeter (CR-221, manufactured by Konica Minolta, Inc.).

In the present disclosure, “(meth)acrylic” is a concept including both acrylic and methacrylic, and “(meth)acryloxy group” is a concept including both an acryloxy group and a methacryloxy group.

In the present disclosure, “alkali-soluble” means that the solubility in 100 g of aqueous solution of 1% by mass sodium carbonate at 22° C. is 0.1 g or more.

In the present disclosure, “solid content” means all components excluding a solvent.

In the present disclosure, unless otherwise specified, terms indicating a positional relationship between one constituent element and another constituent element (for example, “upper” and “lower”) mean a relative positional relationship between one constituent element and another constituent element.

In the present disclosure, a combination of two or more preferred aspects is a more preferred aspect.

<Transfer Film>

Hereinafter, a transfer film according to one aspect of the present disclosure, specifically, a transfer film used for manufacturing a base material for a display panel will be described.

The transfer film includes a temporary support and a transfer layer including a photosensitive layer. The transfer layer may have a monolayer structure or a multilayer structure. The transfer layer may include a photosensitive layer and other layers. Examples of the other layers include a thermoplastic resin layer and an interlayer. The transfer film may include a protective film in addition to the temporary support and the transfer layer. For example, the transfer film may include a temporary support, a transfer layer including a photosensitive layer, and a protective film in this order. Examples of a constitution of the transfer film are shown below. However, the constitution of the transfer film is not limited to the following specific examples.

(1) “temporary support/photosensitive layer”

(2) “temporary support/photosensitive layer/protective film”

(3) “temporary support/interlayer/photosensitive layer/protective film”

(4) “temporary support/thermoplastic resin layer/interlayer/photosensitive layer/protective film”

[Temporary Support]

The transfer film includes a temporary support. The temporary support supports the transfer layer. In use of the transfer film, the temporary support may be finally removed.

The temporary support may be a monolayer structure or a multilayer structure.

The temporary support is preferably a film and more preferably a resin film. As the temporary support, a film which has flexibility and does not generate significant deformation, contraction, or stretching under pressure or under pressure and heating is preferable.

Examples of the film include a polyethylene terephthalate film (for example, a biaxial stretching polyethylene terephthalate film), a polymethylmethacrylate film, a cellulose triacetate film, a polystyrene film, a polyimide film, and a polycarbonate film. As the temporary support, a polyethylene terephthalate film is preferable. In addition, it is preferable that the film used as the temporary support does not have deformation such as wrinkles or scratches.

From the viewpoint that pattern exposure through the temporary support can be performed, the temporary support preferably has high transparency. A transmittance at 365 nm is preferably 60% or more and more preferably 70% or more.

From the viewpoint of pattern formability during pattern exposure through the temporary support and transparency of the temporary support, it is preferable that a haze of the temporary support is small. Specifically, a haze value of the temporary support is preferably 2% or less, more preferably 0.5% or less, and still more preferably 0.1% or less.

From the viewpoint of pattern formability during pattern exposure through the temporary support and transparency of the temporary support, it is preferable that the number of fine particles, foreign substances, and defects included in the temporary support is small. The number of fine particles having a diameter of 1 μm or more, foreign substances, and defects in the temporary support is preferably 50 pieces/10 mm² or less, more preferably 10 pieces/10 mm² or less, still more preferably 3 pieces/10 mm² or less, and particularly preferably 0 piece/10 mm².

A thickness of the temporary support is not particularly limited, but is preferably 5 μm to 200 μm. In addition, from the viewpoint of ease of handling and general-purpose properties, the thickness of the temporary support is more preferably 5 μm to 150 μm, still more preferably 5 μm to 50 μm, and most preferably 5 μm to 25 μm. The thickness of the temporary support is calculated as an average value of any five points measured by a cross-sectional observation with a scanning electron microscope (SEM).

In order to improve adhesiveness between the temporary support and the transfer layer, a surface of the temporary support, facing the transfer layer, may be surface-modified by ultraviolet irradiation, corona discharge, or plasma. In the surface modification by ultraviolet irradiation, an exposure amount is preferably 10 mJ/cm² to 2000 mJ/cm² and more preferably 50 mJ/cm² to 1000 mJ/cm². Examples of a light source for the ultraviolet irradiation include a low pressure mercury lamp, a high pressure mercury lamp, a super high pressure mercury lamp, a carbon arc lamp, a metal halide lamp, a xenon lamp, a chemical lamp, an electrodeless discharge lamp, and a light emitting diode (LED), all of which emit a light in a wavelength range of 150 to 450 nm. As long as the exposure amount is within the above-described range, output and illuminance of the light source are not limited.

Examples of the temporary support include a biaxial stretching polyethylene terephthalate film having a film thickness of 16 μm, a biaxial stretching polyethylene terephthalate film having a film thickness of 12 μm, and a biaxial stretching polyethylene terephthalate film having a film thickness of 9 μm.

Preferred aspects of the temporary support are described in, for example, paragraphs [0017] and [0018] of JP2014-085643A, paragraphs [0019] to [0026] of JP2016-027363A, paragraphs [0041] to [0057] of WO2012/081680A, and paragraphs [0029] to [0040] of WO2018/179370A. The contents of these publications are incorporated herein by reference.

From the viewpoint of imparting handleability, a layer (lubricant layer) including fine particles may be provided on the surface of the temporary support. The lubricant layer may be provided on one side or both sides of the temporary support. A diameter of the particles included in the lubricant layer is preferably 0.05 μm to 0.8 μm. In addition, a film thickness of the lubricant layer is preferably 0.05 μm to 1.0 μm.

Examples of a commercially available product of the temporary support include LUMIRROR 16QS40 and LUMIRROR 16FB40 (all manufactured by Toray Industries, Inc.), and COSMOSHINE A4100, COSMOSHINE A4300, and COSMOSHINE A8300 (all manufactured by TOYOBO Co., Ltd.).

[Photosensitive Layer]

The transfer film includes a photosensitive layer. The photosensitive layer is a constituent element of the transfer layer. In the photosensitive layer, a pattern can be formed through exposure and development. As the photosensitive layer, a negative photosensitive layer is preferable. The negative photosensitive layer is a photosensitive layer in which solubility of an exposed portion in a developer is reduced by the exposure. In a case where the photosensitive layer is a negative photosensitive layer, the formed pattern corresponds to a cured layer.

(Softening Temperature)

A softening temperature of the photosensitive layer after exposure is preferably 300° C. or higher, more preferably 350° C. or higher, and still more preferably 400° C. or higher. In a case where the softening temperature of the photosensitive layer after exposure is 300° C. or higher, thermal stability of the pattern formed from the photosensitive layer is improved. As a result, a pattern in which collapse and deformation are unlikely to occur is obtained. In addition, in a case where the softening temperature of the photosensitive layer after exposure is 300° C. or higher, even in a case where an aspect ratio of the pattern is large, the pattern is less likely to collapse or deform. For example, in a case where the photosensitive layer is used as a material forming a partition wall of a base material for a display panel as described later, a partition wall which is less likely to collapse or deform is obtained. Therefore, a transfer film in which the softening temperature of the photosensitive layer after exposure is adjusted to 300° C. or higher is suitable for manufacturing a base material for a display panel. The upper limit of the softening temperature of the photosensitive layer after exposure is not limited. The softening temperature of the photosensitive layer after exposure may be 800° C. or lower, 700° C. or lower, 600° C. or lower, or 500° C. or lower. The photosensitive layer after exposure may be a photosensitive layer exposed with light having at least one wavelength selected from the group consisting of 365 nm and 405 nm. The photosensitive layer after exposure may be a photosensitive layer exposed with light having a wavelength of 365 nm. The photosensitive layer after exposure may be a photosensitive layer exposed with light having a wavelength of 405 nm. The softening temperature of the photosensitive layer after exposure is measured by an atomic force microscope (AFM). The specific procedure is as follows. First, using a measuring device using an atomic force microscope (for example, a combination of AFM5100N type SPM manufactured by Hitachi High-Tech Science Corporation and a local thermal analysis system nano-TA manufactured by U.S. Analysis Instruments Corporation), an amount of needle (for example, PR-EX-AN2-200-5, 0.6 kΩ to 3.5 kΩ, 55 kHz to 88 kHz, 0.5 N/m to 3 N/m) inserted into a surface of a measurement sample is measured under heating conditions in a temperature range from room temperature (for example, 25° C.) to 500° C. at a heating rate of 10° C./sec. Next, the softening temperature of the measurement sample is obtained based on a graph showing the change in amount of needle inserted with respect to the heating temperature. The above-described series of operations is performed with the number of measurements in a range of 3 to 5 times, and an average value of the softening temperature of the measurement sample is obtained. The average value of the obtained softening temperatures is adopted as the softening temperature in the present disclosure. The softening temperature is corrected based on a difference between a known softening temperature of a standard sample (for example, polycaprolactone, polypropylene, and polyethylene terephthalate) and a softening temperature of the standard sample calculated according to the above-described method for measuring the softening temperature using an atomic force microscope. For example, the softening temperature of the photosensitive layer after exposure is adjusted by a composition of the photosensitive layer. For example, by adjusting the composition of the photosensitive layer so that a component having a high softening temperature is present in the photosensitive layer after exposure, it is possible to contribute to an increase in softening temperature of the photosensitive layer after exposure. For example, the softening temperature of the photosensitive layer after exposure may be adjusted by contents of a crosslinking compound, a polymerization initiator, a sensitizer, and a hydrogen donating compound. The softening temperature of the photosensitive layer after exposure may be adjusted by a type and number of functional groups of the crosslinking compound, a compositional ratio of the crosslinking compound, and a double bond amount of the crosslinking compound. For example, since a crosslinking density of the photosensitive layer after exposure changes depending on the number of crosslinking groups (including polymerizable groups) of the compound included in the photosensitive layer, the softening temperature of the photosensitive layer after exposure may be adjusted by adjusting the crosslinking density.

(Transmittance at Photosensitive Wavelength)

A transmittance of the photosensitive layer at a photosensitive wavelength is preferably 30% or more, more preferably 40% or more, and still more preferably 50% or more. In a case where the transmittance of the photosensitive layer at a photosensitive wavelength is 30% or more, resolution is improved. In addition, in a case where the transmittance of the photosensitive layer at a photosensitive wavelength is 30% or more, high resolution is maintained even in a case where the thickness of the photosensitive layer is increased. As a result, a pattern having a high aspect ratio is obtained. For example, in a case where the photosensitive layer is used as a material forming a partition wall of a base material for a display panel as described later, a partition wall having a high aspect ratio is obtained. Therefore, a transfer film in which the transmittance of the photosensitive layer at a photosensitive wavelength is adjusted to 30% or more is suitable for manufacturing a base material for a display panel. Furthermore, regarding the negative photosensitive layer, in a case where the transmittance of the negative photosensitive layer at a photosensitive wavelength is 30% or more, uniformity of a curing reaction of the negative photosensitive layer in a thickness direction is improved. From the viewpoint of photosensitivity (for example, polymerization rate), the transmittance of the photosensitive layer at a photosensitive wavelength is preferably 95% or less, more preferably 90% or less, and still more preferably 85% or less. The “photosensitive wavelength” means a wavelength to which an object is exposed. The photosensitive wavelength may be at least one wavelength selected from the group consisting of 365 nm and 405 nm. The photosensitive wavelength may be 365 nm. The photosensitive wavelength may be 405 nm. The transmittance of the photosensitive layer at a photosensitive wavelength is measured by a spectrophotometer. The transmittance of the photosensitive layer at a photosensitive wavelength is adjusted, for example, by the composition (for example, the type and content of the initiator and the sensitizer) of the photosensitive layer.

Examples of components of the photosensitive layer include components shown below. The photosensitive layer may include one kind or two or more kinds of components selected from the components shown below. However, the components of the photosensitive layer are not limited to the following specific examples.

(Component: Binder Polymer)

The photosensitive layer may include a binder polymer. Examples of the binder polymer include a (meth)acrylic resin, a styrene resin, an epoxy resin, an amide resin, an amido epoxy resin, an alkyd resin, a phenol resin, an ester resin, a urethane resin, an epoxy acrylate resin obtained by a reaction of an epoxy resin and a (meth)acrylic acid, and acid-modified epoxy acrylate resin obtained by a reaction of an epoxy acrylate resin and acid anhydride.

From the viewpoint of excellent alkali developability and film formability, examples of one suitable aspect of the binder polymer include a (meth)acrylic resin. In the present disclosure, the (meth)acrylic resin means a resin having a constitutional unit derived from a (meth)acrylic compound.

The content of the constitutional unit derived from a (meth)acrylic compound is preferably 50% by mass or more, more preferably 70% by mass or more, and still more preferably 90% by mass or more with respect to all constitutional units of the (meth)acrylic resin.
The (meth)acrylic resin may be composed of only the constitutional unit derived from a (meth)acrylic compound, or may have a constitutional unit derived from a polymerizable monomer other than the (meth)acrylic compound. That is, the upper limit of the content of the constitutional unit derived from a (meth)acrylic compound is 100% by mass or less with respect to all constitutional units of the (meth)acrylic resin.

Examples of the (meth)acrylic compound include (meth)acrylic acid, (meth)acrylic acid ester, (meth)acrylamide, and (meth)acrylonitrile.

Examples of the (meth)acrylic acid ester include (meth)acrylic acid alkyl ester, (meth)acrylic acid tetrahydrofurfuryl ester, (meth)acrylic acid dimethylaminoethyl ester, (meth)acrylic acid diethylaminoethyl ester, (meth)acrylic acid glycidyl ester, (meth)acrylic acid benzyl ester, 2,2,2-trifluoroethyl (meth)acrylate, and 2,2,3,3-tetrafluoropropyl (meth)acrylate, and (meth)acrylic acid alkyl ester is preferable.

An alkyl group of the (meth)acrylic alkyl ester may be linear or branched. Specific examples thereof include (meth)acrylic acid alkyl esters having an alkyl group having 1 to 12 carbon atoms, such as methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, 2-ethylhexyl (meth)acrylate, nonyl (meth)acrylate, decyl (meth)acrylate, undecyl (meth)acrylate, and dodecyl (meth)acrylate.

As the (meth)acrylic acid ester, (meth)acrylic acid alkyl ester having an alkyl group having 1 to 4 carbon atoms is preferable, and methyl (meth)acrylate or ethyl (meth)acrylate is more preferable.

Examples of the (meth)acrylamide include acrylamides such as diacetone acrylamide.

The (meth)acrylic resin may have a constitutional unit other than the constitutional unit derived from a (meth)acrylic compound. The polymerizable monomer forming the above-described constitutional unit is not particularly limited as long as it is a compound other than the (meth)acrylic compound, which can be copolymerized with the (meth)acrylic compound, and examples thereof include styrene compounds which may have a substituent at an α-position or an aromatic ring, such as styrene, vinyltoluene, and α-methylstyrene, vinyl alcohol esters such as acrylonitrile and vinyl-n-butyl ether, maleic acid monoesters such as maleic acid, maleic acid anhydride, monomethyl maleate, monoethyl maleate, and monoisopropyl maleate, fumaric acid, cinnamic acid, α-cyanocinnamic acid, itaconic acid, and crotonic acid. These polymerizable monomers may be used alone or in combination of two or more kinds thereof.

In addition, from the viewpoint of improving alkali developability, the (meth)acrylic resin preferably has a constitutional unit having an acid group. Examples of the acid group include a carboxy group, a sulfo group, a phosphoric acid group, and a phosphonic acid group. Among these, the (meth)acrylic resin more preferably has a constitutional unit having a carboxy group, and still more preferably has a constitutional unit derived from the above-described (meth)acrylic acid.

From the viewpoint of excellent developability, the content of the constitutional unit having an acid group (preferably, the constitutional unit derived from (meth)acrylic acid) in the (meth)acrylic resin is preferably 10% by mass or more with respect to the total mass of the (meth)acrylic resin. In addition, the upper limit value thereof is not particularly limited, but from the viewpoint of excellent alkali resistance, is preferably 50% by mass or less and more preferably 40% by mass or less.

In addition, it is more preferable that the (meth)acrylic resin has a constitutional unit derived from the above-described (meth)acrylic acid alkyl ester.

The content of the constitutional unit derived from (meth)acrylic acid alkyl ester in the (meth)acrylic resin is preferably 50% by mass to 90% by mass, more preferably 60% by mass to 90% by mass, and still more preferably 65% by mass to 90% by mass with respect to all constitutional units of the (meth)acrylic resin.

As the (meth)acrylic resin, a resin having both the constitutional unit derived from (meth)acrylic acid and the constitutional unit derived from (meth)acrylic acid alkyl ester is preferable, and a resin composed only of the constitutional unit derived from (meth)acrylic acid and the constitutional unit derived from (meth)acrylic acid alkyl ester is more preferable.

In addition, as the (meth)acrylic resin, an acrylic resin which has a constitutional unit derived from methacrylic acid, a constitutional unit derived from methyl methacrylate, and a constitutional unit derived from ethyl acrylate is also preferable.

In addition, from the viewpoint that the effects of the present disclosure are more excellent, the (meth)acrylic resin preferably has at least one selected from the group consisting of a constitutional unit derived from methacrylic acid and a constitutional unit derived from methacrylic acid alkyl ester, and preferably has both the constitutional unit derived from methacrylic acid and the constitutional unit derived from methacrylic acid alkyl ester.

From the viewpoint that the effects of the present disclosure are more excellent, the total content of the constitutional unit derived from methacrylic acid and the constitutional unit derived from methacrylic acid alkyl ester in the (meth)acrylic resin is preferably 40% by mass or more and more preferably 60% by mass or more with respect to all constitutional units of the (meth)acrylic resin. The upper limit is not particularly limited, and may be 100% by mass or less, preferably 80% by mass or less.

In addition, from the viewpoint that the effects of the present disclosure are more excellent, it is also preferable that the (meth)acrylic resin has at least one selected from the group consisting of a constitutional unit derived from methacrylic acid and a constitutional unit derived from methacrylic acid alkyl ester, and has at least one selected from the group consisting of a constitutional unit derived from acrylic acid and a constitutional unit derived from acrylic acid alkyl ester. From the viewpoint that the effects of the present disclosure are more excellent, the total content of the constitutional unit derived from methacrylic acid and the constitutional unit derived from methacrylic acid alkyl ester is preferably 60/40 to 80/20 in terms of mass ratio with respect to the total content of the constitutional unit derived from acrylic acid and the constitutional unit derived from acrylic acid alkyl ester.

From the viewpoint of excellent developability of the photosensitive layer after transfer, the (meth)acrylic resin preferably has an ester group at the terminal. The terminal portion of the (meth)acrylic resin is composed of a site derived from a polymerization initiator used in the synthesis. The (meth)acrylic resin having an ester group at the terminal can be synthesized by using a polymerization initiator which generates a radical having an ester group.

In addition, examples of other suitable aspects of the binder polymer include an alkali-soluble resin. From the viewpoint of developability, for example, the binder polymer is preferably a binder polymer having an acid value of 60 mgKOH/g or more. In addition, from the viewpoint that it is easy to form a strong film by thermally crosslinking with a crosslinking component by heating, for example, the binder polymer is more preferably a resin (so-called a carboxy group-containing resin) having an acid value of 60 mgKOH/g or more and having a carboxy group, and still more preferably a (meth)acrylic resin (so-called a carboxy group-containing (meth)acrylic resin) having an acid value of 60 mgKOH/g or more and having a carboxy group. In a case where the binder polymer is a resin having a carboxy group, for example, the three-dimensional crosslinking density can be increased by adding a thermal crosslinking compound such as a blocked isocyanate compound and thermally crosslinking. In addition, in a case where the carboxy group of the resin having a carboxy group is anhydrous and hydrophobized, wet heat resistance can be improved.

The carboxy group-containing (meth)acrylic resin having an acid value of 60 mgKOH/g or more is not particularly limited as long as the above-described conditions of acid value are satisfied, and a known (meth)acrylic resin can be appropriately selected. For example, a carboxy group-containing acrylic resin having an acid value of 60 mgKOH/g or more among polymers described in paragraph [0025] of JP2011-095716A, a carboxy group-containing acrylic resin having an acid value of 60 mgKOH/g or more among polymers described in paragraphs [0033] to [0052] of JP2010-237589A, and the like can be preferably used.

Examples of other suitable aspects of the binder polymer include a styrene-acrylic copolymer. In the present disclosure, the styrene-acrylic copolymer refers to a resin having a constitutional unit derived from a styrene compound and a constitutional unit derived from a (meth)acrylic compound, and the total content of the constitutional unit derived from a styrene compound and the constitutional unit derived from a (meth)acrylic compound is preferably 30% by mass or more and more preferably 50% by mass or more with respect to all constitutional units of the copolymer. In addition, the content of the constitutional unit derived from a styrene compound is preferably 1% by mass or more, more preferably 5% by mass or more, and still more preferably 5% by mass to 80% by mass with respect to the all constitutional units of the above-described copolymer. In addition, the content of the constitutional unit derived from the above-described (meth)acrylic compound is preferably 5% by mass or more, more preferably 10% by mass or more, and still more preferably 20% by mass to 95% by mass with respect to the all constitutional units of the above-described copolymer.

From the viewpoint that the effects of the present disclosure are more excellent, the binder polymer preferably has an aromatic ring structure, and more preferably has a constitutional unit having an aromatic ring structure. Examples of a monomer forming the constitutional unit having an aromatic ring structure include a monomer having an aralkyl group, styrene, and a polymerizable styrene derivative (for example, methylstyrene, vinyltoluene, tert-butoxystyrene, acetoxystyrene, 4-vinylbenzoic acid, styrene dimer, and styrene trimer). Among these, a monomer having an aralkyl group or styrene is preferable. Examples of the aralkyl group include a substituted or unsubstituted phenylalkyl group (excluding a benzyl group), and a substituted or unsubstituted benzyl group, and a substituted or unsubstituted benzyl group is preferable.

Examples of a monomer having the phenylalkyl group include phenylethyl (meth)acrylate.

Examples of a monomer having the benzyl group include (meth)acrylates having a benzyl group, such as benzyl (meth)acrylate and chlorobenzyl (meth)acrylate; and vinyl monomers having a benzyl group, such as vinylbenzyl chloride and vinylbenzyl alcohol. Among these, benzyl (meth)acrylate is preferable.

In addition, from the viewpoint that the effects of the present disclosure are more excellent, the binder polymer more preferably has a constitutional unit represented by Formula (S) (constitutional unit derived from styrene).

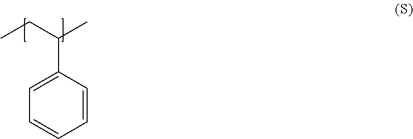

In a case where the binder polymer has the constitutional unit having an aromatic ring structure, from the viewpoint that the effects of the present disclosure are more excellent, the content of the constitutional unit having an aromatic ring structure is preferably 5% by mass to 90% by mass, more preferably 10% by mass to 70% by mass, and still more preferably 20% by mass to 60% by mass with respect to the all constitutional units of the binder polymer.

In addition, from the viewpoint that the effects of the present disclosure are more excellent, the content of the constitutional unit having an aromatic ring structure in the binder polymer is preferably 5 mol % to 70 mol %, more preferably 10 mol % to 60 mol %, and still more preferably 20 mol % to 60 mol % with respect to all constitutional units of the binder polymer.

Further, from the viewpoint that the effects of the present disclosure are more excellent, the content of the constitutional unit represented by Formula (S) in the binder polymer is preferably 5 mol % to 70 mol %, more preferably 10 mol % to 60 mol %, still more preferably 20 mol % to 60 mol %, and particularly preferably 20 mol % to 50 mol % with respect to all constitutional units of the binder polymer.

In the present disclosure, in a case where the content of a “constitutional unit” is defined by a molar ratio, the “constitutional unit” is synonymous with the “monomer unit”. In addition, in the present disclosure, the “monomer unit” may be modified after polymerization by a polymer reaction or the like. The same applies to the following.

From the viewpoint that the effects of the present disclosure are more excellent, the binder polymer preferably has an aliphatic hydrocarbon ring structure. That is, the binder polymer preferably has a constitutional unit having an aliphatic hydrocarbon ring structure. The aliphatic hydrocarbon ring structure may be monocyclic or polycyclic. Among these, the binder polymer more preferably has a ring structure in which two or more aliphatic hydrocarbon rings are fused.

Examples of a ring constituting the aliphatic hydrocarbon ring structure in the constitutional unit having an aliphatic hydrocarbon ring structure include a tricyclodecane ring, a cyclohexane ring, a cyclopentane ring, a norbomane ring, and an isophorone ring. Among these, from the viewpoint that the effects of the present disclosure are more excellent, a ring in which two or more aliphatic hydrocarbon rings are fused is preferable, and a tetrahydrodicyclopentadiene ring (tricyclo[5.2.1.0^{2,6}]decane ring) is more preferable.

Examples of a monomer forming the constitutional unit having an aliphatic hydrocarbon ring structure include dicyclopentanyl (meth)acrylate, cyclohexyl (meth)acrylate, and isobornyl (meth)acrylate.

In addition, from the viewpoint that the effects of the present disclosure are more excellent, the binder polymer more preferably has a constitutional unit represented by Formula (Cy), and more preferably has the constitutional unit represented by Formula (S) and the constitutional unit represented by Formula (Cy).

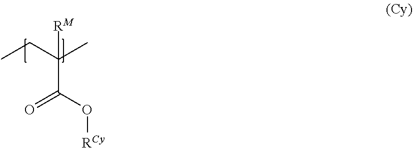

In Formula (Cy), R^{M} represents a hydrogen atom or a methyl group, and R^{Cy} represents a monovalent group having an aliphatic hydrocarbon ring structure.

R^{M} in Formula (Cy) is preferably a methyl group.

From the viewpoint that the effects of the present disclosure are more excellent, R^{Cy} in Formula (Cy) is preferably a monovalent group having an aliphatic hydrocarbon ring structure having 5 to 20 carbon atoms, more preferably a monovalent group having an aliphatic hydrocarbon ring structure having 6 to 16 carbon atoms, and still more preferably a monovalent group having an aliphatic hydrocarbon ring structure having 8 to 14 carbon atoms.

In addition, from the viewpoint that the effects of the present disclosure are more excellent, the aliphatic hydrocarbon ring structure in R^{Cy} of Formula (Cy) is preferably a cyclopentane ring structure, a cyclohexane ring structure, a tetrahydrodicyclopentadiene ring structure, a norbomane ring structure, or an isophorone ring structure, more preferably a cyclohexane ring structure or a tetrahydrodicyclopentadiene ring structure, and still more preferably a tetrahydrodicyclopentadiene ring structure.

Further, from the viewpoint that the effects of the present disclosure are more excellent, the aliphatic hydrocarbon ring structure in R^{Cy} of Formula (Cy) is preferably a ring structure in which two or more aliphatic hydrocarbon rings are fused, and more preferably a ring in which two to four aliphatic hydrocarbon rings are fused.

Further, from the viewpoint that the effects of the present disclosure are more excellent, R^{Cy} in Formula (Cy) is preferably a group in which the oxygen atom in —C(═O)O— of Formula (Cy) and the aliphatic hydrocarbon ring structure are directly bonded, that is, an aliphatic hydrocarbon ring group, more preferably a cyclohexyl group or a dicyclopentanyl group, and still more preferably a dicyclopentanyl group.

The binder polymer may have one constitutional unit having an aliphatic hydrocarbon ring structure alone, or two or more kinds thereof.

In a case where the binder polymer has the constitutional unit having an aliphatic hydrocarbon ring structure, from the viewpoint that the effects of the present disclosure are more excellent, the content of the constitutional unit having an aliphatic hydrocarbon ring structure is preferably 5% by mass to 90% by mass, more preferably 10% by mass to 80% by mass, and still more preferably 20% by mass to 70% by mass with respect to the all constitutional units of the binder polymer.

In addition, from the viewpoint that the effects of the present disclosure are more excellent, the content of the constitutional unit having an aliphatic hydrocarbon ring structure in the binder polymer is preferably 5 mol % to 70 mol %, more preferably 10 mol % to 60 mol %, and still more preferably 20 mol % to 50 mol % with respect to all constitutional units of the binder polymer.

Further, from the viewpoint that the effects of the present disclosure are more excellent, the content of the constitutional unit represented by Formula (Cy) in the binder polymer is preferably 5 mol % to 70 mol %, more preferably 10 mol % to 60 mol %, and still more preferably 20 mol % to 50 mol % with respect to all constitutional units of the binder polymer.

In a case where the binder polymer includes the constitutional unit having an aromatic ring structure and the constitutional unit having an aliphatic hydrocarbon ring structure, from the viewpoint that the effects of the present disclosure are more excellent, the total content of the constitutional unit having an aromatic ring structure and the constitutional unit having an aliphatic hydrocarbon ring structure is preferably 10% by mass to 90% by mass, more preferably 20% by mass to 80% by mass, and particularly preferably 40% by mass to 75% by mass with respect to all constitutional units of the binder polymer.

In addition, from the viewpoint that the effects of the present disclosure are more excellent, the total content of the constitutional unit having an aromatic ring structure and the constitutional unit having an aliphatic hydrocarbon ring structure in the binder polymer is preferably 10 mol % to 80 mol %, more preferably 20 mol % to 70 mol %, and still more preferably 40 mol % to 60 mol % with respect to all constitutional units of the binder polymer.

Further, from the viewpoint that the effects of the present disclosure are more excellent, the total content of the constitutional unit represented by Formula (S) and the constitutional unit represented by Formula (Cy) in the binder polymer is preferably 10 mol % to 80 mol %, more preferably 20 mol % to 70 mol %, and still more preferably 40 mol % to 60 mol % with respect to all constitutional units of the binder polymer.

In addition, from the viewpoint that the effects of the present disclosure are more excellent, a molar amount nS of the constitutional unit represented by Formula (S) and a molar amount nCy of the constitutional unit represented by Formula (Cy) in the binder polymer preferably satisfy the relationship shown in the following expression (SCy), more preferably satisfy the following expression (SCy-1), and still more preferably satisfy the following expression (SCy-2).

0.2≤nS/(nS+nCy)≤0.8 Expression (SCy)

0.30≤nS/(nS+nCy)≤0.75 Expression (SCy-1)

0.40≤nS/(nS+nCy)≤0.70 Expression (SCy-2)

From the viewpoint that the effects of the present disclosure are more excellent, the binder polymer preferably has a constitutional unit having an acid group. Examples of the above-described acid group include a carboxy group, a sulfo group, a phosphonic acid group, and a phosphoric acid group, and a carboxy group is preferable. As the above-described constitutional unit having an acid group, constitutional units derived from (meth)acrylic acid, which are shown below, is preferable, and a constitutional unit derived from methacrylic acid is more preferable.

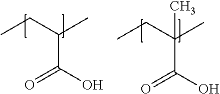

The binder polymer may have one constitutional unit having an acid group alone, or two or more kinds thereof.

In a case where the binder polymer has the constitutional unit having an acid group, from the viewpoint that the effects of the present disclosure are more excellent, the content of the constitutional unit having an acid group is preferably 5% by mass to 50% by mass, more preferably 5% by mass to 40% by mass, and still more preferably 10% by mass to 30% by mass with respect to the all constitutional units of the binder polymer.

In addition, from the viewpoint that the effects of the present disclosure are more excellent, the content of the constitutional unit having an acid group in the binder polymer is preferably 5 mol % to 70 mol %, more preferably 10 mol % to 50 mol %, and still more preferably 20 mol % to 40 mol % with respect to all constitutional units of the binder polymer.

Further, from the viewpoint that the effects of the present disclosure are more excellent, the content of the constitutional unit derived from (meth)acrylic acid in the binder polymer is preferably 5 mol % to 70 mol %, more preferably 10 mol % to 50 mol %, and still more preferably 20 mol % to 40 mol % with respect to all constitutional units of the binder polymer.

From the viewpoint that the effects of the present disclosure are more excellent, the binder polymer preferably has a reactive group, and more preferably has a constitutional unit having a reactive group. As the reactive group, a radically polymerizable group is preferable, and an ethylenically unsaturated group is more preferable. In addition, in a case where the binder polymer has an ethylenically unsaturated group, the binder polymer preferably has a constitutional unit having an ethylenically unsaturated group in the side chain. In the present disclosure, the “main chain” represents a relatively longest binding chain in a molecule of a polymer compound constituting a resin, and the “side chain” represents an atomic group branched from the main chain.

As the ethylenically unsaturated group, an allyl group or a (meth)acryloxy group is more preferable.

Examples of the constitutional unit having a reactive group include those shown below, but the constitutional unit having a reactive group is not limited thereto.

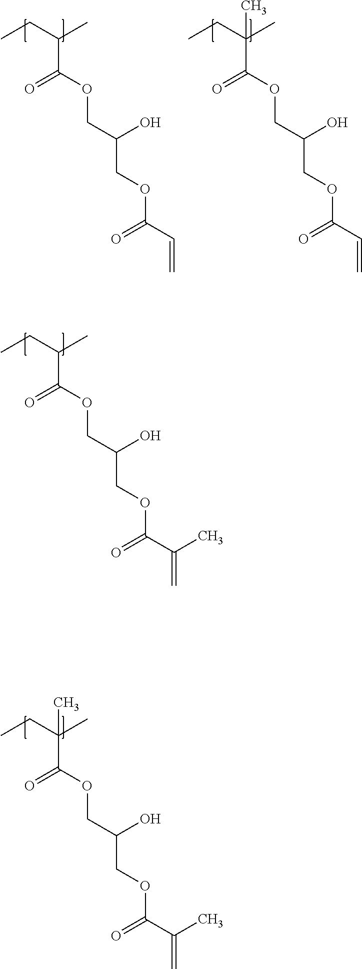

The binder polymer may have one constitutional unit having a reactive group alone, or two or more kinds thereof.

In a case where the binder polymer has the constitutional unit having a reactive group, from the viewpoint that the effects of the present disclosure are more excellent, the content of the constitutional unit having a reactive group is preferably 5% by mass to 70% by mass, more preferably 10% by mass to 50% by mass, and still more preferably 20% by mass to 40% by mass with respect to the all constitutional units of the binder polymer.

In addition, from the viewpoint that the effects of the present disclosure are more excellent, the content of the constitutional unit having a reactive group in the binder polymer is preferably 5 mol % to 70 mol %, more preferably 10 mol % to 60 mol %, and still more preferably 20 mol % to 50 mol % with respect to all constitutional units of the binder polymer.

Examples of a method for introducing the reactive group into the binder polymer include a method of reacting a compound such as an epoxy compound, a blocked isocyanate compound, an isocyanate compound, a vinyl sulfone compound, an aldehyde compound, a methylol compound, and a carboxylic acid anhydride with a functional group such as a hydroxy group, a carboxy group, a primary amino group, a secondary amino group, an acetoacetyl group, and a sulfo group.

Preferred examples of the method for introducing the reactive group into the binder polymer include a method in which a polymer having a carboxy group is synthesized by a polymerization reaction, and then a glycidyl (meth)acrylate is reacted with a part of the carboxy group of the obtained polymer by a polymer reaction, thereby introducing a (meth)acryloxy group into the polymer. By this method, a binder polymer having a (meth)acryloxy group in the side chain can be obtained. The above-described polymerization reaction is preferably carried out under a temperature condition of 70° C. to 100° C., and more preferably carried out under a temperature condition of 80° C. to 90° C. As a polymerization initiator used in the above-described polymerization reaction, an azo-based initiator is preferable, and for example, V-601 (product name) or V-65 (product name) manufactured by FUJIFILM Wako Pure Chemical Corporation is more preferable. The above-described polymer reaction is preferably carried out under a temperature condition of 80° C. to 110° C. In the above-described polymer reaction, it is preferable to use a catalyst such as an ammonium salt.

As the binder polymer, from the viewpoint that the effects of the present disclosure are more excellent, polymers shown below are more preferable. Content ratios (a to d) and weight-average molecular weights Mw of each of the constitutional units shown below can be appropriately changed according to the purpose.

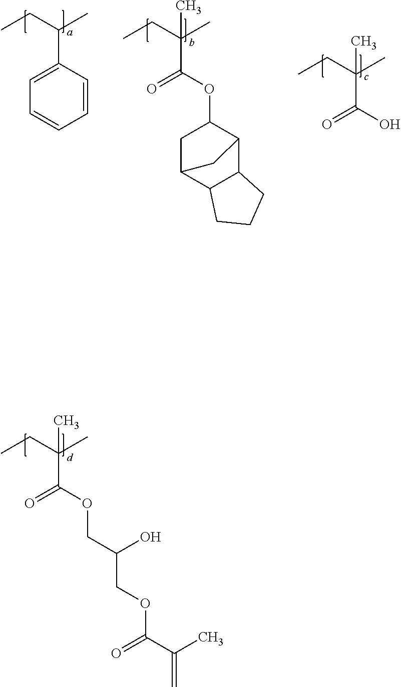

Preferred ranges of the content ratios (a to d) of each of the above-described constitutional units are shown below.
a: 20% by mass to 60% by mass
b: 10% by mass to 50% by mass
c: 5.0% by mass to 25% by mass
d: 10% by mass to 50% by mass

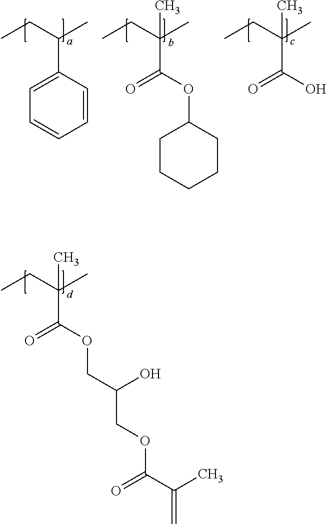

Preferred ranges of the content ratios (a to d) of each of the above-described constitutional units are shown below.
a: 20% by mass to 60% by mass
b: 10% by mass to 50% by mass
c: 5.0% by mass to 25% by mass
d: 10% by mass to 50% by mass

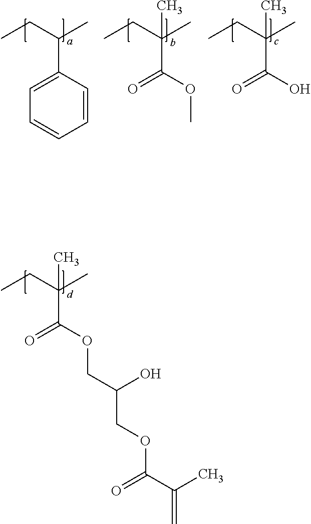

Preferred ranges of the content ratios (a to d) of each of the above-described constitutional units are shown below.
a: 30% by mass to 65% by mass
b: 1.0% by mass to 20% by mass
c: 5.0% by mass to 25% by mass
d: 10% by mass to 50% by mass

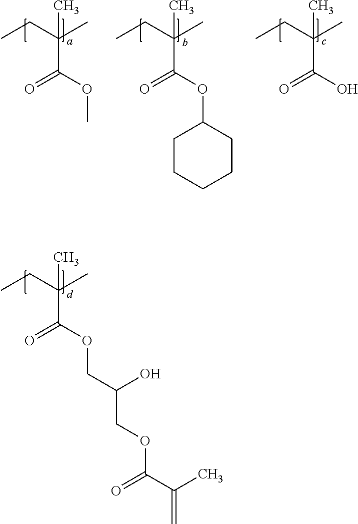

Preferred ranges of the content ratios (a to d) of each of the above-described constitutional units are shown below.
a: 1.0% by mass to 20% by mass
b: 20% by mass to 60% by mass
c: 5.0% by mass to 25% by mass
d: 10% by mass to 50% by mass

In addition, the binder polymer may include a polymer (hereinafter, also referred to as a “polymer X”) having a constitutional unit having a carboxylic acid anhydride structure. The carboxylic acid anhydride structure may be either a chain carboxylic acid anhydride structure or a cyclic carboxylic acid anhydride structure, and a cyclic carboxylic acid anhydride structure is preferable. The ring of the cyclic carboxylic acid anhydride structure is preferably a 5- to 7-membered ring, more preferably a 5-membered ring or a 6-membered ring, and still more preferably a 5-membered ring.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or through a divalent linking group.

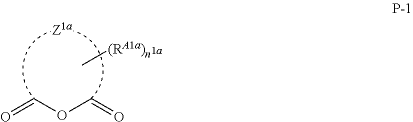

In Formula P-1, R^{A1a} represents a substituent, n^{1a} pieces of R^{A1a}'s may be the same or different, Z^{1a} represents a divalent group forming a ring including —C(═O)—O—C(═O)—, and n^{1a} represents an integer of 0 or more.

Examples of the substituent represented by R^{A1a} include an alkyl group.

Z^{1a} is preferably an alkylene group having 2 to 4 carbon atoms, more preferably an alkylene group having 2 or 3 carbon atoms, and still more preferably an alkylene group having 2 carbon atoms.

n^{1a} represents an integer of 0 or more. In a case where Z^{1a} represents an alkylene group having 2 to 4 carbon atoms, n^{1a} is preferably an integer of 0 to 4, more preferably an integer of 0 to 2, and still more preferably 0.

In a case where n^{1a} represents an integer of 2 or more, a plurality of R^{A1a}'s existing may be the same or different. In addition, the plurality of R^{A1a}'s existing may be bonded to each other to form a ring, but it is preferable that they are not bonded to each other to form a ring.

As the constitutional unit having a carboxylic acid anhydride structure, a constitutional unit derived from an unsaturated carboxylic acid anhydride is preferable, a constitutional unit derived from an unsaturated cyclic carboxylic acid anhydride is more preferable, a constitutional unit derived from an unsaturated aliphatic carboxylic acid anhydride is still more preferable, a constitutional unit derived from maleic anhydride or itaconic anhydride is particularly preferable, and a constitutional unit derived from maleic acid anhydride is most preferable.

Hereinafter, specific examples of the constitutional unit having a carboxylic acid anhydride structure will be described, but the constitutional unit having a carboxylic acid anhydride structure is not limited to these specific examples. In the following constitutional units, Rx represents a hydrogen atom, a methyl group, a CH₂OH group, or a CF₃ group, and Me represents a methyl group.

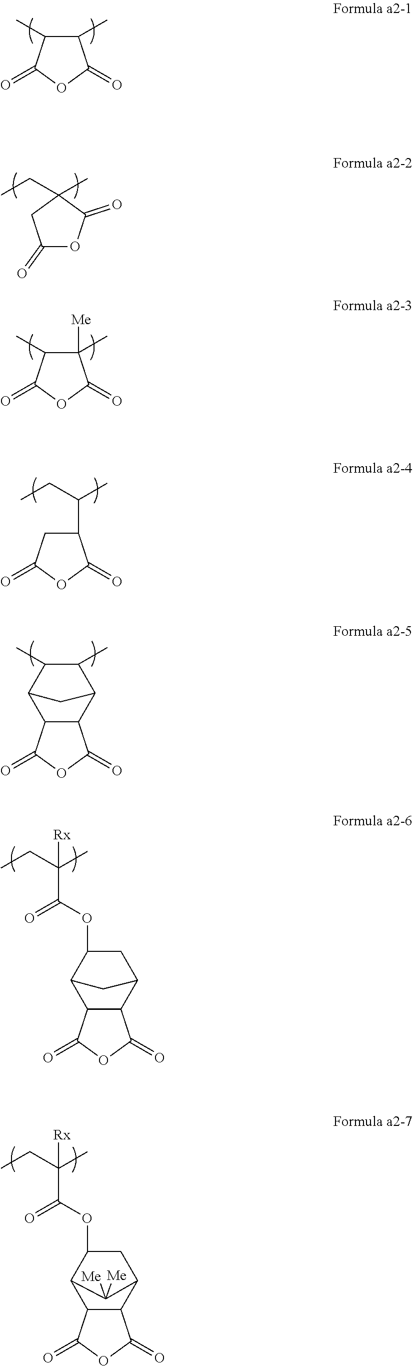

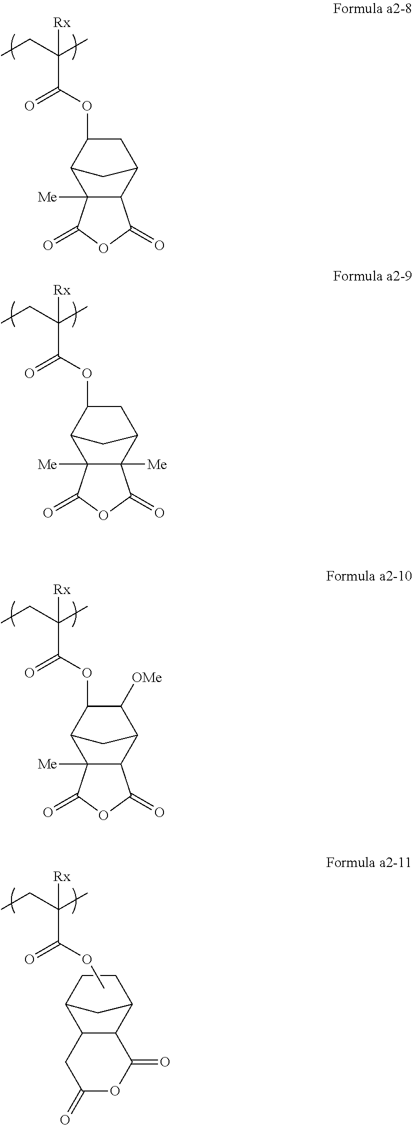

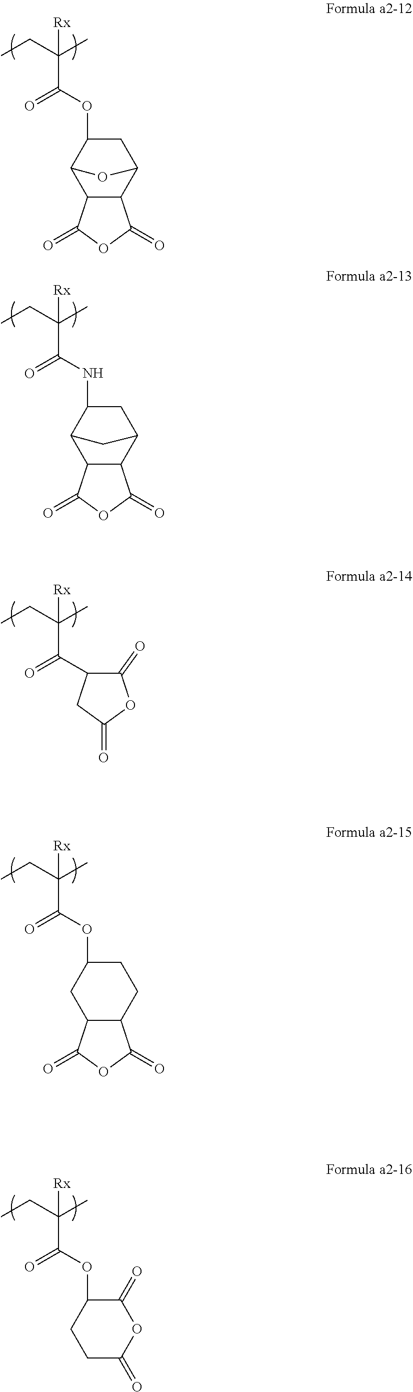

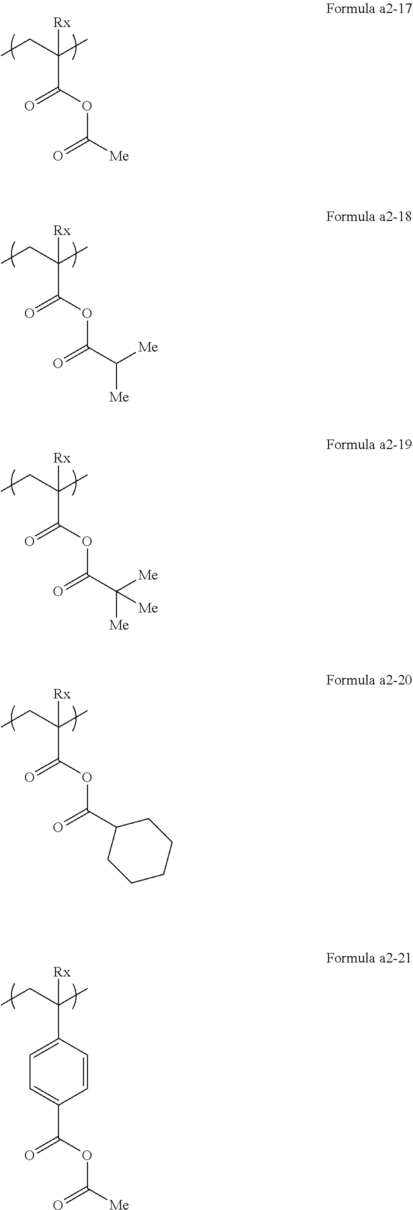

The polymer X may have one constitutional unit having a carboxylic acid anhydride structure alone, or two or more kinds thereof.

The total content of the constitutional unit having a carboxylic acid anhydride structure is preferably 0 mol % to 60 mol %, more preferably 5 mol % to 40 mol %, and still more preferably 10 mol % to 35 mol % with respect to all constitutional units of the polymer X.

The photosensitive layer may include only one kind of the polymer X, or may include two or more kinds thereof.

In a case where the photosensitive layer includes the polymer X, from the viewpoint that the effects of the present disclosure are more excellent, the content of the polymer X is preferably 0.1% by mass to 30% by mass, more preferably 0.2% by mass to 20% by mass, still more preferably 0.5% by mass to 20% by mass, and particularly preferably 1% by mass to 20% by mass with respect to the total mass of the photosensitive layer.

From the viewpoint that the effects of the present disclosure are more excellent, a weight-average molecular weight (Mw) of the binder polymer is preferably 5,000 or more, more preferably 10,000 or more, still more preferably 10,000 to 50,000, and particularly preferably 20,000 to 30,000.

From the viewpoint of developability, a dispersity of the binder polymer is preferably 1.0 to 6.0, more preferably 1.0 to 5.0, still more preferably 1.0 to 4.0, and particularly preferably 1.0 to 3.0.

An acid value of the binder polymer is preferably 10 mgKOH/g to 200 mgKOH/g, more preferably 60 mgKOH/g to 200 mgKOH/g, still more preferably 60 mgKOH/g to 150 mgKOH/g, and particularly preferably 70 mgKOH/g to 125 mgKOH/g. The acid value of the binder polymer is a value measured according to the method described in JIS K0070: 1992.

The photosensitive layer may include only one kind of the binder polymer, or may include two or more kinds thereof.

From the viewpoint that the effects of the present disclosure are more excellent, a content of the binder polymer is preferably 10% by mass to 90% by mass, more preferably 20% by mass to 80% by mass, and still more preferably 30% by mass to 70% by mass with respect to the total mass of the photosensitive layer.

(Component: Polymerizable Compound)

The photosensitive layer may include a polymerizable compound. The polymerizable compound is a compound having a polymerizable group. Examples of the polymerizable group include a radically polymerizable group and a cationically polymerizable group, and a radically polymerizable group is preferable. It is preferable that the photosensitive layer includes a polymerizable compound having at least one polymerizable group selected from the group consisting of a vinyl group, an acryloyl group, a methacryloyl group, a styryl group, and a maleimide group.

The polymerizable compound preferably includes a radically polymerizable compound having an ethylenically unsaturated group (hereinafter, also simply referred to as an “ethylenically unsaturated compound”). As the ethylenically unsaturated group, a (meth)acryloxy group is preferable. The ethylenically unsaturated compound in the present specification is a compound other than the above-described binder polymer, and preferably has a molecular weight of less than 5,000.

Examples of one suitable aspect of the polymerizable compound include a compound represented by Formula (M) (simply referred to as a “compound M”).

Q²-R¹-Q¹ Formula (M)

In Formula (M), Q¹ and Q² each independently represent a (meth)acryloyloxy group, and R¹ represents a divalent linking group having a chain structure.

From the viewpoint of easiness of synthesis, Q¹ and Q² in Formula (M) preferably have the same group. In addition, from the viewpoint of reactivity, Q¹ and Q² in Formula (M) are preferably acryloyloxy groups.

From the viewpoint that the effects of the present disclosure are more excellent, R¹ in Formula (M) is preferably an alkylene group, an alkyleneoxyalkylene group (-L¹-O-L¹), or a polyalkyleneoxyalkylene group (-(L¹-O)ₚ-L¹-), more preferably a hydrocarbon group having 2 to 20 carbon atoms or a polyalkyleneoxyalkylene group, still more preferably an alkylene group having 4 to 20 carbon atoms, and particularly preferably a linear alkylene group having 6 to 18 carbon atoms. It is sufficient that the above-described hydrocarbon group has a chain structure at least in part, and a portion other than the chain structure is not particularly limited. For example, the portion may be a branched chain, a cyclic or a linear alkylene group having 1 to 5 carbon atoms, an arylene group, an ether bond, or a combination thereof, and an alkylene group or a group in which two or more alkylene groups and one or more arylene groups are combined is preferable, an alkylene group is more preferable, and a linear alkylene group is still more preferable. The above-described L¹'s each independently represent an alkylene group, and an ethylene group, a propylene group, or a butylene group is preferable and an ethylene group or a 1,2-propylene group is more preferable. p represents an integer of 2 or more, and is preferably an integer of 2 to 10.

In addition, from the viewpoint that the effects of the present disclosure are more excellent, the number of atoms in the shortest linking chain which links Q¹ and Q² in the compound M is preferably 3 to 50, more preferably 4 to 40, still more preferably 6 to 20, and particularly preferably 8 to 12. In the present disclosure, the “number of atoms in the shortest linking chain which links Q¹ and Q²” is the shortest number of atoms linking from an atom in R¹ linked to Q¹ to an atom in R¹ linked to Q².

Specific examples of the compound M include 1,3-butanediol di(meth)acrylate, tetramethylene glycol di(meth)acrylate, neopentyl glycol di(meth)acrylate, 1,6-hexanediol di(meth)acrylate, 1,7-heptanediol di(meth)acrylate, 1,8-octanediol di(meth)acrylate, 1,9-nonanediol di(meth)acrylate, 1,10-decanediol di(meth)acrylate, hydrogenated bisphenol A di(meth)acrylate, hydrogenated bisphenol F di(meth)acrylate, polyethylene glycol di(meth)acrylate, polypropylene glycol di(meth)acrylate, poly (ethylene glycol/propylene glycol) di(meth)acrylate, and polybutylene glycol di(meth)acrylate. The above-described ester monomers can also be used as a mixture. Among the above-described compounds, from the viewpoint that the effects of the present disclosure are more excellent, at least one compound selected from the group consisting of 1,6-hexanediol di(meth)acrylate, 1,9-nonanediol di(meth)acrylate, 1,10-decanediol di(meth)acrylate, and neopentyl glycol di(meth)acrylate is preferable, at least one compound selected from the group consisting of 1,6-hexanediol di(meth)acrylate, 1,9-nonanediol di(meth)acrylate, and 1,10-decanediol di(meth)acrylate is more preferable, and at least one compound selected from the group consisting of 1,9-nonanediol di(meth)acrylate and 1,10-decanediol di(meth)acrylate is still more preferable.

In addition, examples of one suitable aspect of the polymerizable compound include a bi- or higher functional ethylenically unsaturated compound. In the present disclosure, the “bi- or higher functional ethylenically unsaturated compound” means a compound having two or more ethylenically unsaturated groups in one molecule. As the ethylenically unsaturated group in the ethylenically unsaturated compound, a (meth)acryloyl group is preferable. As the ethylenically unsaturated compound, a (meth)acrylate compound is preferable.

The bifunctional ethylenically unsaturated compound is not particularly limited and can be appropriately selected from a known compound. Examples of the bifunctional ethylenically unsaturated compound other than the above-described compound M include tricyclodecane dimethanol di(meth)acrylate and 1,4-cyclohexanediol di(meth)acrylate.

Examples of a commercially available product of the bifunctional ethylenically unsaturated compound include tricyclodecane dimethanol diacrylate (product name: NK ESTER A-DCP, manufactured by Shin-Nakamura Chemical Co., Ltd.), tricyclodecane dimethanol dimethacrylate (product name: NK ESTER DCP, manufactured by Shin-Nakamura Chemical Co., Ltd.), 1,9-nonanediol diacrylate (product name: NK ESTER A-NOD-N, manufactured by Shin-Nakamura Chemical Co., Ltd.), and 1,6-hexanediol diacrylate (product name: NK ESTER A-HD-N, manufactured by Shin-Nakamura Chemical Co., Ltd.).

The tri- or higher functional ethylenically unsaturated compound is not particularly limited and can be appropriately selected from a known compound. Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton. Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the polymerizable compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD (registered trademark) RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like), and ethoxylated glycerin triacrylate (NK ESTER A-GLY-9E manufactured by Shin-Nakamura Chemical Co., Ltd., or the like).

Examples of the polymerizable compound also include a urethane (meth)acrylate compound. Examples of the urethane (meth)acrylate include urethane di(meth)acrylate, and examples thereof include propylene oxide-modified urethane di(meth)acrylate and ethylene oxide and propylene oxide-modified urethane di(meth)acrylate. In addition, examples of the urethane (meth)acrylate also include tri- or higher functional urethane (meth)acrylate. The lower limit of the number of functional groups is more preferably 6 or more and still more preferably 8 or more. The upper limit of the number of functional groups is preferably 20 or less. Examples of the tri- or higher functional urethane (meth)acrylate include 8UX-015A (manufactured by Taisei Fine Chemical Co., Ltd.), UA-32P (manufactured by Shin-Nakamura Chemical Co., Ltd.), U-15HA (manufactured by Shin-Nakamura Chemical Co., Ltd.), UA-1100H (manufactured by Shin-Nakamura Chemical Co., Ltd.), AH-600 (product name) manufactured by KYOEISHA CHEMICAL Co., LTD, UA-306H, UA-306T, UA-3061, UA-510H, and UX-5000 (all manufactured by Nippon Kayaku Co., Ltd.).

Examples of one suitable aspect of the polymerizable compound include an ethylenically unsaturated compound having an acid group. Examples of the acid group include a phosphoric acid group, a sulfo group, and a carboxy group. Among these, as the acid group, a carboxy group is preferable.

Examples of the ethylenically unsaturated compound having an acid group include a tri- or tetra-functional ethylenically unsaturated compound having an acid group [component obtained by introducing a carboxy group to pentaerythritol tri- and tetra-acrylate (PETA) skeleton (acid value: 80 mgKOH/g to 120 mgKOH/g)), and a penta- to hexa-functional ethylenically unsaturated compound having an acid group [component obtained by introducing a carboxy group to dipentaerythritol penta- and hexa-acrylate (DPHA) skeleton (acid value: 25 to 70 mgKOH/g)]. The tri- or higher functional ethylenically unsaturated compound having an acid group may be used in combination with the bifunctional ethylenically unsaturated compound having an acid group, as necessary.

As the ethylenically unsaturated compound having an acid group, at least one selected from the group consisting of bi- or higher functional ethylenically unsaturated compound having a carboxy group and a carboxylic acid anhydride thereof is preferable. In a case where the ethylenically unsaturated compound having an acid group is at least one selected from the group consisting of bi- or higher functional ethylenically unsaturated compound having a carboxy group and a carboxylic acid anhydride thereof, developability and film hardness are further enhanced. The bi- or higher functional ethylenically unsaturated compound having a carboxy group is not particularly limited and can be appropriately selected from a known compound. Examples of the bi- or higher functional ethylenically unsaturated compound having a carboxy group include ARONIX (registered trademark) TO-2349 manufactured by Toagosei Co., Ltd., ARONIX (registered trademark) M-520 manufactured by Toagosei Co., Ltd., and ARONIX (registered trademark) M-510 manufactured by Toagosei Co., Ltd.

As the ethylenically unsaturated compound having an acid group, polymerizable compounds having an acid group, which are described in paragraphs [0025] to [0030] of JP2004-239942A, are preferable, and the contents described in this publication are incorporated in the present specification.

Examples of the polymerizable compound also include a compound obtained by reacting a polyhydric alcohol with an α,β-unsaturated carboxylic acid, a compound obtained by reacting a glycidyl group-containing compound with an α,β-unsaturated carboxylic acid, urethane monomer such as a (meth)acrylate compound having a urethane bond, phthalate compounds such as γ-chloro-β-hydroxypropyl-β′-(meth)acryloyloxyethyl-o-phthalate, β-hydroxyethyl-β′-(meth)acryloyloxyethyl-o-phthalate, and β-hydroxypropyl-β′-(meth)acryloyloxyethyl-o-phthalate, and (meth)acrylic acid alkyl esters. These compounds may be used alone or in combination of two or more kinds thereof.

Examples of the compound obtained by reacting a polyhydric alcohol with an α,β-unsaturated carboxylic acid include bisphenol A-based (meth)acrylate compounds such as 2,2-bis(4-((meth)acryloxypolyethoxy)phenyl)propane, 2,2-bis(4-((meth)acryloxypolypropoxy)phenyl)propane, and 2,2-bis(4-((meth)acryloxypolyethoxypolypropoxy)phenyl)propane, polyethylene glycol di(meth)acrylate having 2 to 14 ethylene oxide groups, polypropylene glycol di(meth)acrylate having 2 to 14 propylene oxide groups, polyethylene polypropylene glycol di(meth)acrylate having 2 to 14 ethylene oxide groups and 2 to 14 propylene oxide groups, trimethylolpropane di(meth)acrylate, trimethylolpropane tri(meth)acrylate, trimethylolpropane ethoxy tri(meth)acrylate, trimethylolpropane diethoxy tri(meth)acrylate, trimethylolpropane triethoxy tri(meth)acrylate, trimethylolpropane tetraethoxy tri(meth)acrylate, trimethylolpropane pentaethoxy tri(meth)acrylate, di(trimethylolpropane) tetraacrylate, tetramethylolmethane tri(meth)acrylate, tetramethylolmethane tetra(meth)acrylate, dipentaerythritol tetra(meth)acrylate, dipentaerythritol penta(meth)acrylate, and dipentaerythritol hexa(meth)acrylate. Among these, an ethylenically unsaturated compound having a tetramethylolmethane structure or a trimethylolpropane structure is preferable, and tetramethylolmethane tri(meth)acrylate, tetramethylolmethane tetra(meth)acrylate, trimethylolpropane tri(meth)acrylate, or di(trimethylolpropane) tetraacrylate is more preferable.

Examples of the polymerizable compound also include a caprolactone-modified compound of ethylenically unsaturated compound (for example, KAYARAD (registered trademark) DPCA-20 manufactured by Nippon Kayaku Co., Ltd., A-9300-1CL manufactured by Shin-Nakamura Chemical Co., Ltd., and the like), an alkylene oxide-modified compound of ethylenically unsaturated compound (for example, KAYARAD RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., and the like), and ethoxylated glycerin triacrylate (A-GLY-9E manufactured by Shin-Nakamura Chemical Co., Ltd., and the like).

Among these, as the polymerizable compound (particularly, the ethylenically unsaturated compound), from the viewpoint of excellent developability of the photosensitive layer after transfer, an ethylenically unsaturated compound including an ester bond is also preferable. The ethylenically unsaturated compound including an ester bond is not particularly limited as long as it includes an ester bond in the molecule, but from the viewpoint that the effects of the present disclosure are excellent, an ethylenically unsaturated compound having a tetramethylolmethane structure or a trimethylolpropane structure is preferable, and tetramethylolmethane tri(meth)acrylate, tetramethylolmethane tetra(meth)acrylate, trimethylolpropane tri(meth)acrylate, or di(trimethylolpropane) tetraacrylate is more preferable.

As the ethylenically unsaturated compound, from the viewpoint of imparting reliability, it is preferable to include an ethylenically unsaturated compound having an aliphatic group having 6 to 20 carbon atoms and the above-described ethylenically unsaturated compound having a tetramethylolmethane structure or a trimethylolpropane structure. Examples of the ethylenically unsaturated compound having an aliphatic group having 6 to 20 carbon atoms include 1,9-nonanediol di(meth)acrylate, 1,10-decanediol di(meth)acrylate, and tricyclodecane dimethanol di(meth)acrylate.

Examples of one suitable aspect of the polymerizable compound include a polymerizable compound (preferably, a bifunctional ethylenically unsaturated compound) having an aliphatic hydrocarbon ring structure. As the above-described polymerizable compound, a polymerizable compound having a ring structure in which two or more aliphatic hydrocarbon rings are fused (preferably, a structure selected from the group consisting of a tricyclodecane structure and a tricyclodecene structure) is preferable, a bifunctional ethylenically unsaturated compound having a ring structure in which two or more aliphatic hydrocarbon rings are fused is more preferable, and tricyclodecane dimethanol di(meth)acrylate is still more preferable. As the above-described aliphatic hydrocarbon ring structure, from the viewpoint that the effects of the present disclosure are more excellent, a cyclopentane structure, a cyclohexane structure, a tricyclodecane structure, a tricyclodecene structure, a norbomane structure, or an isophorone structure is preferable.

A molecular weight of the polymerizable compound is preferably 200 to 3,000, more preferably 250 to 2,600, still more preferably 280 to 2,200, and particularly preferably 300 to 2,200.

A proportion of a content of a polymerizable compound having a molecular weight of 300 or less in the polymerizable compounds included in the photosensitive layer is preferably 30% by mass or less, more preferably 25% by mass or less, and still more preferably 20% by mass or less with respect to the content of all the polymerizable compounds included in the photosensitive layer.

As one suitable aspect of the photosensitive layer, the photosensitive layer preferably includes the bi- or higher functional ethylenically unsaturated compound, more preferably includes the tri- or higher functional ethylenically unsaturated compound, and still more preferably includes a tri- or tetrafunctional ethylenically unsaturated compound.

In addition, as one suitable aspect of the photosensitive layer, the photosensitive layer includes the bifunctional ethylenically unsaturated compound having an aliphatic hydrocarbon ring structure and the binder polymer having the constitutional unit having an aliphatic hydrocarbon ring.

In addition, as one suitable aspect of the photosensitive layer, the photosensitive layer preferably includes the compound represented by Formula (M) and the ethylenically unsaturated compound having an acid group, more preferably includes 1,9-nonanediol diacrylate, tricyclodecane dimethanol diacrylate, and a polyfunctional ethylenically unsaturated compound having a carboxylic acid group, and still more preferably includes 1,9-nonanediol diacrylate, tricyclodecane dimethanol diacrylate, and a succinic acid-modified form of dipentaerythritol pentaacrylate.

In addition, as one suitable aspect of the photosensitive layer, the photosensitive layer preferably includes the compound represented by Formula (M), the ethylenically unsaturated compound having an acid group, and a thermal crosslinking compound described later, and more preferably includes the compound represented by Formula (M), the ethylenically unsaturated compound having an acid group, and a blocked isocyanate compound described later.

In addition, as one suitable aspect of the photosensitive layer, from the viewpoint of development residue inhibitory property and rust preventive property, the photosensitive layer preferably includes the bifunctional ethylenically unsaturated compound (preferably, a bifunctional (meth)acrylate compound) and the tri- or higher functional ethylenically unsaturated compound (preferably, a tri- or higher functional (meth)acrylate compound).

A mass ratio of a content of the bifunctional ethylenically unsaturated compound and a content of the tri- or higher functional ethylenically unsaturated compound is preferably 10:90 to 90:10 and more preferably 30:70 to 70:30.

The content of the bifunctional ethylenically unsaturated compound is preferably 20% to 80% by mass and more preferably 30% by mass to 70% by mass with respect to the total amount of all ethylenically unsaturated compounds.

The bifunctional ethylenically unsaturated compound in the photosensitive layer is preferably 10% by mass to 60% by mass and more preferably 15% by mass to 40% by mass.

In addition, as one suitable aspect of the photosensitive layer, from the viewpoint of rust preventive property, the photosensitive layer preferably includes the compound M and the bifunctional ethylenically unsaturated compound having an aliphatic hydrocarbon ring structure.

In addition, as one suitable aspect of the photosensitive layer, from the viewpoint of substrate adhesiveness, development residue inhibitory property, and rust preventive property, the photosensitive layer preferably includes the compound M and the ethylenically unsaturated compound having an acid group, more preferably includes the compound M, the bifunctional ethylenically unsaturated compound having an aliphatic hydrocarbon ring structure, and the ethylenically unsaturated compound having an acid group, still more preferably includes the compound M, the bifunctional ethylenically unsaturated compound having an aliphatic hydrocarbon ring structure, the tri- or higher functional ethylenically unsaturated compound, and the ethylenically unsaturated compound having an acid group, and particularly preferably includes the compound M, the bifunctional ethylenically unsaturated compound having an aliphatic hydrocarbon ring structure, the tri- or higher functional ethylenically unsaturated compound, the ethylenically unsaturated compound having an acid group, and the urethane (meth)acrylate compound.

In addition, as one suitable aspect of the photosensitive layer, from the viewpoint of substrate adhesiveness, development residue inhibitory property, and rust preventive property, the photosensitive layer preferably includes 1,9-nonanediol diacrylate and the polyfunctional ethylenically unsaturated compound having a carboxylic acid group, more preferably includes 1,9-nonanediol diacrylate, tricyclodecane dimethanol diacrylate, and the polyfunctional ethylenically unsaturated compound having a carboxylic acid group, still more preferably includes 1,9-nonanediol diacrylate, tricyclodecane dimethanol diacrylate, dipentaerythritol hexaacrylate, and an ethylenically unsaturated compound having a carboxylic acid group, and particularly preferably includes 1,9-nonanediol diacrylate, tricyclodecane dimethanol diacrylate, an ethylenically unsaturated compound having a carboxylic acid group, and a urethane acrylate compound.

The photosensitive layer may include a monofunctional ethylenically unsaturated compound as the ethylenically unsaturated compound. The content of the bi- or higher functional ethylenically unsaturated compound in the above-described ethylenically unsaturated compound is preferably 60% by mass to 100% by mass, more preferably 80% by mass to 100% by mass, and still more preferably 90% by mass to 100% by mass with respect to the total content of all ethylenically unsaturated compounds included in the photosensitive layer.

The polymerizable compound (particularly, the ethylenically unsaturated compound) may be used alone or in combination of two or more kinds thereof.

A content of the polymerizable compound (particularly, the ethylenically unsaturated compound) in the photosensitive layer is preferably 1% by mass to 70% by mass, more preferably 5% by mass to 70% by mass, still more preferably 5% by mass to 60% by mass, and particularly preferably 5% by mass to 50% by mass with respect to the total mass of the photosensitive layer.

(Component: Polymerization Initiator)

The photosensitive layer may include a polymerization initiator. As the polymerization initiator, a photopolymerization initiator is preferable.

The photopolymerization initiator is not particularly limited and a known photopolymerization initiator can be used. Examples of the photopolymerization initiator include a compound having an oxime ester structure (hereinafter, also referred to as an “oxime-based photopolymerization initiator”), a compound having an α-aminoalkylphenone structure (hereinafter, also referred to as an “α-aminoalkylphenone-based photopolymerization initiator”), a compound having an α-hydroxyalkylphenone structure (hereinafter also referred to as an “α-hydroxyalkylphenone-based photopolymerization initiator”), a compound having an acylphosphine oxide structure, (hereinafter, also referred to as an “acylphosphine oxide-based photopolymerization initiator”), a compound having a triarylimidazole structure (hereinafter, also referred to as a “triarylimidazole-based photopolymerization initiator”), and a photopolymerization initiator having an N-phenylglycine structure (hereinafter, also referred to as an “N-phenylglycine-based photopolymerization initiator”). It is preferable that the photosensitive layer includes at least one photopolymerization initiator selected from the group consisting of a compound having an oxime ester structure, a compound having an α-hydroxyalkylphenone structure, a compound having an acylphosphine oxide structure, and a compound having a triarylimidazole structure.

In addition, as the photopolymerization initiator, for example, polymerization initiators described in paragraphs [0031] to [0042] of JP2011-95716A and paragraphs [0064] to [0081] of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(O-acetyloxime) [product name: IRGACURE (registered trademark) OXE-02, manufactured by BASF SE], IRGACURE (registered trademark) OXE-03 (manufactured by BASF SE), IRGACURE (registered trademark) OXE-04 (manufactured by BASF SE), 2-(dimethylamino)-2-[(4-methylphenyl)methyl]-1-[4-(4-morpholinyl)phenyl]-1-butanone [product name: Omnirad (registered trademark) 379EG, manufactured by IGM Resins B.V.], 2-methyl-1-(4-methylthiophenyl)-2-morpholinopropan-1-one [product name: Omnirad (registered trademark) 907, manufactured by IGM Resins B.V.], 2-hydroxy-1-{4-[4-(2-hydroxy-2-methylpropionyl)benzyl]phenyl}-2-methylpropan-1-one [product name: Omnirad (registered trademark) 127, manufactured by IGM Resins B.V.], 2-benzyl-2-dimethylamino-1-(4-morpholinophenyl)butanone-1 [product name: Omnirad (registered trademark) 369, manufactured by IGM Resins B.V.], 2-hydroxy-2-methyl-1-phenylpropan-1-one [product name: Omnirad (registered trademark) 1173, manufactured by IGM Resins B.V.], 1-hydroxy cyclohexyl phenyl ketone [product name: Omnirad (registered trademark) 184, manufactured by IGM Resins B.V.], 2,2-dimethoxy-1,2-diphenylethan-1-one (product name: Omnirad (registered trademark) 651, manufactured by IGM Resins B.V.], an oxime ester-based product [product name: Lunar (registered trademark) 6, manufactured by DKSH Management Ltd.], 1-[4-(phenylthio)phenyl]-3-cyclopentylpropan-1,2-dione-2-(O-benzoyloxime) (product name: TR-PBG-305, manufactured by TRONLY), 1,2-propanedione, 3-cyclohexyl-1-[9-ethyl-6-(2-furanylcarbonyl)-9H-carbazole-3-yl]2-(O-acetyloxime) (product name: TR-PBG-326, manufactured by TRONLY), 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by TRONLY), and APi-307 (1-(biphenyl-4-yl)-2-methyl-2-morpholinopropan-1-one, manufactured by Shenzhen UV ChemTech Co., Ltd.).

The photopolymerization initiator may be used alone or in combination of two or more kinds thereof. In a case of using two or more kinds thereof, it is preferable to use at least one selected from the oxime-based photopolymerization initiator, the α-aminoalkylphenone-based photopolymerization initiator, or the α-hydroxyalkylphenone-based photopolymerization initiator.

In a case where the photosensitive layer includes the photopolymerization initiator, a content of the photopolymerization initiator is preferably 0.1% by mass or more, more preferably 0.5% by mass or more, and still more preferably 1.0% by mass or more with respect to the total mass of the photosensitive layer. In addition, the upper limit thereof is preferably 10% by mass or less and more preferably 5% by mass or less with respect to the total mass of the photosensitive layer.

(Component: Heterocyclic Compound)

The photosensitive layer may include a heterocyclic compound. A heterocyclic ring included in the heterocyclic compound may be either a monocyclic or polycyclic heterocyclic ring. Examples of a heteroatom included in the heterocyclic compound include an oxygen atom, a nitrogen atom, and a sulfur atom. The heterocyclic compound preferably has at least one atom selected from the group consisting of a nitrogen atom, an oxygen atom, and a sulfur atom, and more preferably has a nitrogen atom.

Examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound. Among the above-described compounds, the heterocyclic compound is preferably at least one compound selected from the group consisting of a triazole compound, a benzotriazole compound, a tetrazole compound, a thiadiazole compound, a triazine compound, a rhodanine compound, a thiazole compound, a benzimidazole compounds, and a benzoxazole compound, and more preferably at least one compound selected from the group consisting of a triazole compound, a benzotriazole compound, a tetrazole compound, a thiadiazole compound, a thiazole compound, a benzothiazole compound, a benzimidazole compound, and a benzoxazole compound.

Preferred specific examples of the heterocyclic compound are shown below. Examples of the triazole compound and the benzotriazole compound include the following compounds.

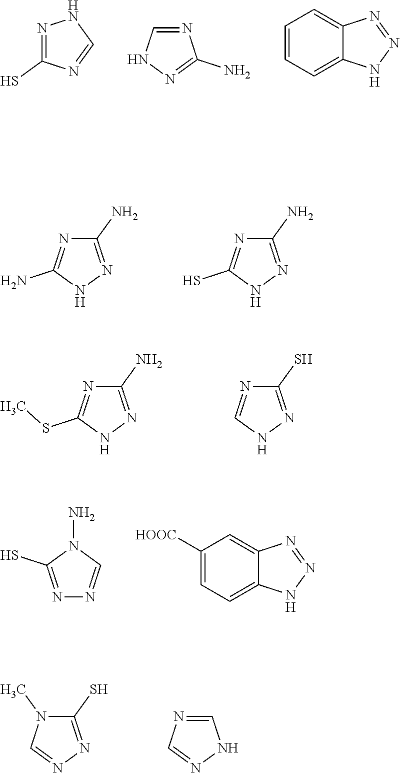

Examples of the tetrazole compound include the following compounds.

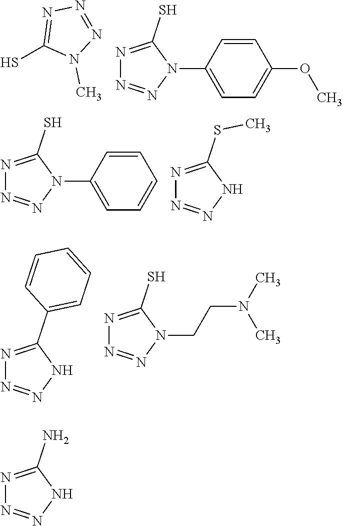

Examples of the thiadiazole compound include the following compounds.

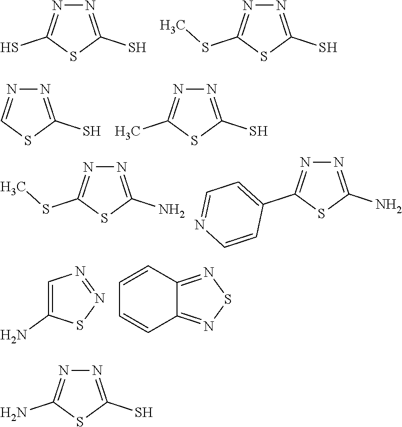

Examples of the triazine compound include the following compounds.

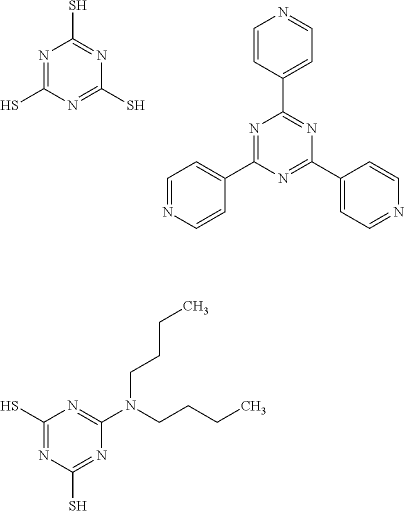 [SMILES: Sc1nc(S)nc(S)n1 ; c1cc(-c2nc(-c3ccncc3)nc(-c3ccncc3)n2)ccn1 ; CCCCN(CCCC)c1nc(S)nc(S)n1]

Examples of the rhodanine compound include the following compounds.

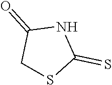

Examples of the thiazole compound include the following compounds.

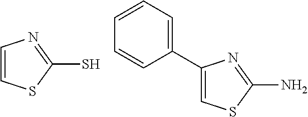

Examples of the benzothiazole compound include the following compounds.

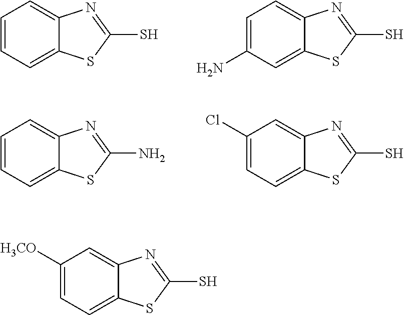 [SMILES: Sc1nc2ccccc2s1 ; Nc1ccc2nc(S)sc2c1 ; Nc1nc2ccccc2s1 ; Sc1nc2cc(Cl)ccc2s1 ; COc1ccc2sc(S)nc2c1]

Examples of the benzimidazole compound include the following compounds.

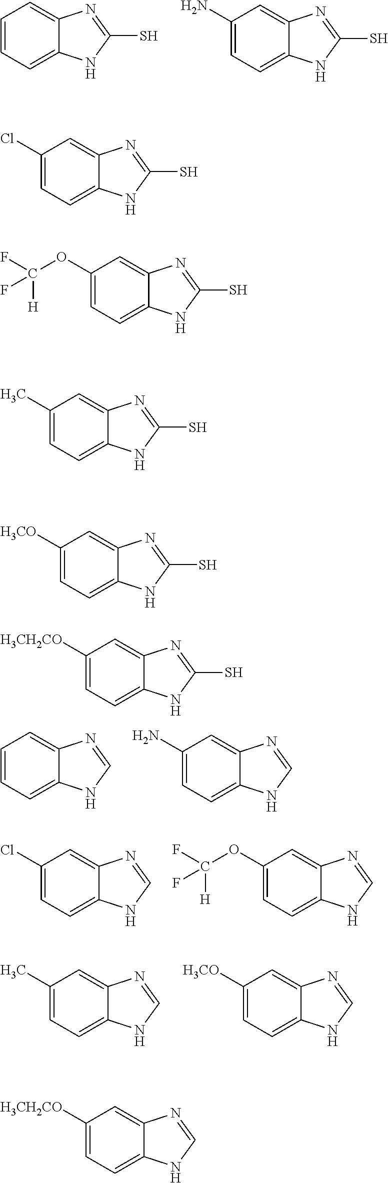

Examples of the benzoxazole compound include the following compounds.

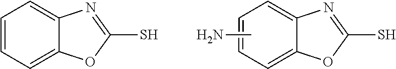

The heterocyclic compound may be used alone or in combination of two or more kinds thereof.

In a case where the photosensitive layer includes the heterocyclic compound, a content of the heterocyclic compound is preferably 0.01% by mass to 20.0% by mass, more preferably 0.10% by mass to 10.0% by mass, still more preferably 0.30% by mass to 8.0% by mass, and particularly preferably 0.50% by mass to 5.0% by mass with respect to the total mass of the photosensitive layer.

(Component: Aliphatic Thiol Compound)

The photosensitive layer may include an aliphatic thiol compound. In a case where the photosensitive layer includes an aliphatic thiol compound, an ene-thiol reaction of the aliphatic thiol compound with the radically polymerizable compound having an ethylenically unsaturated group suppresses a curing contraction of the formed film and relieves stress.

As the aliphatic thiol compound, a monofunctional aliphatic thiol compound or a polyfunctional aliphatic thiol compound (that is, bi- or higher functional aliphatic thiol compound) is preferable. Among the above-described compounds, as the aliphatic thiol compound, from the viewpoint of adhesiveness of the formed pattern (particularly, adhesiveness after exposure), a polyfunctional aliphatic thiol compound is preferable. In the present disclosure, the “polyfunctional aliphatic thiol compound” refers to an aliphatic compound having two or more thiol groups (also referred to as “mercapto groups”) in a molecule.

As the polyfunctional aliphatic thiol compound, a low-molecular-weight compound having a molecular weight of 100 or more is preferable. Specifically, the molecular weight of the polyfunctional aliphatic thiol compound is more preferably 100 to 1,500 and still more preferably 150 to 1,000.

From the viewpoint of adhesiveness of the formed pattern, for example, the number of functional groups in the polyfunctional aliphatic thiol compound is preferably 2 to 10, more preferably 2 to 8, and still more preferably 2 to 6.

Examples of the polyfunctional aliphatic thiol compound include trimethylolpropane tris(3-mercaptobutyrate), 1,4-bis(3-mercaptobutyryloxy)butane, pentaerythritol tetrakis(3-mercaptobutyrate), 1,3,5-tris(3-mercaptobutyryloxyethyl)-1,3,5-triazine-2,4,6(1H,3H,5H)-trione, trimethylolethane tris(3-mercaptobutyrate), tris[(3-mercaptopropionyloxy)ethyl]isocyanurate, trimethylolpropane tris(3-mercaptopropionate), pentaerythritol tetrakis(3-mercaptopropionate), tetraethylene glycol bis(3-mercaptopropionate), dipentaerythritol hexakis(3-mercaptopropionate), ethylene glycol bisthiopropionate, 1,2-ethanedithiol, 1,3-propanedithiol, 1,6-hexamethylenedithiol, 2,2′-(ethylenedithio)diethanethiol, meso-2,3-dimercaptosuccinic acid, and di(mercaptoethyl) ether.

Among the above-described compounds, the polyfunctional aliphatic thiol compound is preferably at least one compound selected from the group consisting of trimethylolpropane tris(3-mercaptobutyrate), 1,4-bis(3-mercaptobutyryloxy)butane, and 1,3,5-tris(3-mercaptobutyryloxyethyl)-1,3,5-triazine-2,4,6(1H,3H,5H)-trione.

Examples of the monofunctional aliphatic thiol compound include 1-octanethiol, 1-dodecanethiol, β-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

The photosensitive layer may include only one kind of the aliphatic thiol compound, or may include two or more kinds of the aliphatic thiol compounds.

In a case where the photosensitive layer includes the aliphatic thiol compound, a content of the aliphatic thiol compound is preferably 5% by mass or more, more preferably 5% by mass to 50% by mass, still more preferably 5% by mass to 30% by mass, and particularly preferably 8% by mass to 20% by mass with respect to the total mass of the photosensitive layer.

(Component: Crosslinking Compound)

From the viewpoint of hardness of a cured film to be obtained and pressure-sensitive adhesiveness of an uncured film to be obtained, the photosensitive layer preferably includes a crosslinking compound.

The crosslinking compound is preferably a thermal crosslinking compound. In the present disclosure, a thermal crosslinking compound having an ethylenically unsaturated group, which will be described later, is not treated as the ethylenically unsaturated compound, but is treated as the thermal crosslinking compound.

Examples of the thermal crosslinking compound include an epoxy compound, an oxetane compound, a methylol compound, and a blocked isocyanate compound. Among these, from the viewpoint of hardness of a cured film to be obtained and pressure-sensitive adhesiveness of an uncured film to be obtained, a blocked isocyanate compound is preferable.

Since the blocked isocyanate compound reacts with a hydroxy group and a carboxy group, for example, in a case where at least one of the binder polymer or the radically polymerizable compound having an ethylenically unsaturated group has at least one of a hydroxy group or a carboxy group, hydrophilicity of the formed film tends to decrease, and the function as a protective film tends to be strengthened. The blocked isocyanate compound refers to a “compound having a structure in which the isocyanate group of isocyanate is protected (so-called masked) with a blocking agent”.

A dissociation temperature of the blocked isocyanate compound is not particularly limited, but is preferably 100° C. to 160° C. and more preferably 130° C. to 150° C. The dissociation temperature of blocked isocyanate means “temperature at an endothermic peak accompanied with a deprotection reaction of blocked isocyanate, in a case where the measurement is performed by differential scanning calorimetry (DSC) analysis using a differential scanning calorimeter”. As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include an active methylene compound [diester malonates (dimethyl malonate, diethyl malonate, di-n-butyl malonate, di-2-ethylhexyl malonate, and the like)], and an oxime compound (compound having a structure represented by —C(═N—OH)— in a molecule, such as formaldoxime, acetoaldoxime, acetoxime, methyl ethyl ketoxime, and cyclohexanoneoxime).

Among these, from the viewpoint of storage stability, the blocking agent having a dissociation temperature of 100° C. to 160° C. is preferably, for example, at least one selected from oxime compounds.

From the viewpoint of improving brittleness of the film and improving the adhesion to a transferred material, for example, the blocked isocyanate compound preferably has an isocyanurate structure. The blocked isocyanate compound having an isocyanurate structure can be obtained, for example, by isocyanurate-forming and protecting hexamethylene diisocyanate. Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound may have a polymerizable group. The polymerizable group is not particularly limited, and a known polymerizable group can be used, and a radically polymerizable group is preferable. Examples of the polymerizable group include a (meth)acryloxy group, a (meth)acrylamide group, an ethylenically unsaturated group such as styryl group, and an epoxy group such as a glycidyl group. Among these, as the polymerizable group, an ethylenically unsaturated group is preferable, a (meth)acryloxy group is more preferable, and an acryloxy group still more preferable.

As the blocked isocyanate compound, a commercially available product can be used. Examples of the commercially available product of the blocked isocyanate compound include Karenz (registered trademark) AOI-BM, Karenz (registered trademark) MOI-BM, Karenz (registered trademark) MOI-BP, and the like (all of which are manufactured by SHOWA DENKO K.K.), and block-type DURANATE series (for example, DURANATE (registered trademark) TPA-B80E, DURANATE (registered trademark) WT32-B75P, and the like manufactured by Asahi Kasei Corporation).

The crosslinking compound may be used alone or in combination of two or more kinds thereof.

In a case where the photosensitive layer includes the crosslinking compound, a content of the thermal crosslinking compound is preferably 1% by mass to 50% by mass and more preferably 5% by mass to 30% by mass with respect to the total mass of the photosensitive layer.

(Component: Surfactant)

The photosensitive layer may include a surfactant. Examples of the surfactant include surfactants described in paragraph [0017 of JP4502784B and paragraphs [0060] to [0071] of JP2009-237362A. As the surfactant, a nonionic surfactant, a fluorine-based surfactant, or a silicone-based surfactant is preferable.

Examples of a commercially available product of the fluorine-based surfactant include: MEGAFACE F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily (Feb. 22, 2016) and Nikkei Business Daily (Feb. 23, 2016)), for example, MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound is also preferably used.

In addition, as the fluorine-based surfactant, a block polymer can also be used.

In addition, as the fluorine-based surfactant, a fluorine-containing polymer compound including a constitutional unit derived from a (meth)acrylate compound having a fluorine atom and a constitutional unit derived from a (meth)acrylate compound having 2 or more (preferably 5 or more) alkyleneoxy groups (preferably ethyleneoxy groups or propyleneoxy groups) can also be preferably used.

In addition, as the fluorine-based surfactant, a fluorine-containing polymer having an ethylenically unsaturated bond in the side chain can also be used. Examples thereof include MEGAFACE RS-101, RS-102, RS-718K, and RS-72-K (all of which are manufactured by DIC Corporation.

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (all of which are manufactured by BASF SE), TETRONIC 304, 701, 704, 901, 904, and 150R1 (all of which are manufactured by BASF SE), SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicone-based surfactant include a linear polymer consisting of a siloxane bond and a modified siloxane polymer with an organic group introduced in the side chain or the terminal.

Specific examples of the silicone-based surfactant include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all of which are manufactured by Shin-Etsu Silicone Co., Ltd.), F-4440, TSF-4300, TSF-4445, TSF-4460, and TSF-4452 (all of which are manufactured by Momentive Performance Materials Co., Ltd.), and BYK307, BYK323, and BYK330 (all of which are manufactured by BYK Chemie).

The surfactant may be used alone or in combination of two or more kinds thereof.

In a case where the photosensitive layer includes the surfactant, a content of the surfactant is preferably 0.01% by mass to 3.0% by mass, more preferably 0.01% by mass to 1.0% by mass, and still more preferably 0.05% by mass to 0.80% by mass with respect to the total mass of the photosensitive layer.

(Component: Polymerization Inhibitor)

The photosensitive layer may include a polymerization inhibitor. The polymerization inhibitor means a compound having a function of delaying or prohibiting a polymerization reaction. As the polymerization inhibitor, for example, a known compound used as a polymerization inhibitor can be used.

Examples of the polymerization inhibitor include phenothiazine compounds such as phenothiazine, bis-(1-dimethylbenzyl)phenothiazine, and 3,7-dioctylphenothiazine; hindered phenolic compounds such as bis[3-(3-tert-butyl-4-hydroxy-5-methylphenyl)propionic acid][ethylene bis(oxyethylene)], 2,4-bis[(laurylthio)methyl]-o-cresol, 1,3,5-tris(3,5-di-t-butyl-4-hydroxybenzyl), 1,3,5-tris(4-t-butyl-3-hydroxy-2,6-dimethylbenzyl), 2,4-bis-(n-octylthio)-6-(4-hydroxy-3,5-di-t-butylanilino)-1,3,5-triazine, and pentaerythritol tetrakis3-(3,5-di-tert-butyl-4-hydroxyphenyl)propionate; nitroso compounds or a salt thereof, such as 4-nitrosophenol, N-nitrosodiphenylamine, N-nitrosocyclohexylhydroxylamine, and N-nitrosophenylhydroxylamine; quinone compounds such as methylhydroquinone, t-butylhydroquinone, 2,5-di-t-butylhydroquinone, and 4-benzoquinone; phenolic compounds such as 4-methoxyphenol, 4-methoxy-1-naphthol, and t-butylcatechol; and metal salt compounds such as copper dibutyldithiocarbamate, copper diethyldithiocarbamate, manganese diethyldithiocarbamate, and manganese diphenyldithiocarbamate. Among these, as the polymerization inhibitor, from the viewpoint that the effects of the present disclosure are more excellent, at least one selected from the group consisting of a phenothiazine compound, a nitroso compound or a salt thereof, and a hindered phenolic compound is preferable, and phenothiazine, bis[3-(3-tert-butyl-4-hydroxy-5-methylphenyl)propionic acid][ethylene bis(oxyethylene)], 2,4-bis[(laurylthio)methyl]-o-cresol, 1,3,5-tris(3,5-di-t-butyl-4-hydroxybenzyl), p-methoxyphenol, or an aluminum salt of N-nitrosophenylhydroxylamine is more preferable.

The polymerization inhibitor may be used alone or in combination of two or more kinds thereof.

In a case where the photosensitive layer includes the polymerization inhibitor, a content of the polymerization inhibitor is preferably 0.001% by mass to 5.0% by mass, more preferably 0.01% by mass to 3.0% by mass, and still more preferably 0.02% by mass to 2.0% by mass with respect to the total mass of the photosensitive layer. The content of the polymerization inhibitor is preferably 0.005% by mass to 5.0% by mass, more preferably 0.01% by mass to 3.0% by mass, and still more preferably 0.01% by mass to 1.0% by mass with respect to the total mass of the polymerizable compound.

(Component: Hydrogen Donating Compound)

The photosensitive layer may include a hydrogen donating compound. The hydrogen donating compound has a function of further improving sensitivity of the photopolymerization initiator to actinic ray, suppressing inhibition of polymerization of the polymerizable compound by oxygen, or the like.

Examples of the hydrogen donating compound include amines and an amino acid compound.

Examples of the amines include compounds described in M. R. Sander et al., “Journal of Polymer Society,” Vol. 10, page 3173 (1972), JP1969-020189B (JP-S44-020189B), JP1976-082102A (JP-551-082102A), JP1977-134692A (JP-S52-134692A), JP1984-138205A (JP-S59-138205A), JP1985-084305A (JP-560-084305A), JP1987-018537A (JP-562-018537A), JP1989-033104A (JP-564-033104A), and Research Disclosure 33825. More specific examples thereof include 4,4′-bis(diethylamino)benzophenone, tris(4-dimethylaminophenyl)methane (another name: Leucocrystal Violet), triethanolamine, p-dimethylaminobenzoic acid ethyl ester, p-formyldimethylaniline, and p-methylthiodimethylaniline. Among these, as the amines, from the viewpoint that the effects of the present disclosure are more excellent, at least one selected from the group consisting of 4,4′-bis(diethylamino)benzophenone and tris(4-dimethylaminophenyl)methane is preferable.

Examples of the amino acid compound include N-phenylglycine, N-methyl-N-phenylglycine, and N-ethyl-N-phenylglycine. Among these, as the amino acid compound, from the viewpoint that the effects of the present disclosure are more excellent, N-phenylglycine is preferable.

In addition, examples of the hydrogen donating compound also include an organic metal compound described in JP1973-042965B (JP-548-042965B) (tributyl tin acetate and the like), a hydrogen donor described in JP1980-034414B (JP-S55-034414B), and a sulfur compound described in JP1994-308727A (JP-H6-308727A) (trithiane and the like).

The hydrogen donating compound may be used alone or in combination of two or more kinds thereof.

In a case where the photosensitive layer includes the hydrogen donating compound, from the viewpoint of improving a curing rate by balancing the polymerization growth rate and chain transfer, a content of the hydrogen donating compound is preferably 0.01% by mass to 10.0% by mass, more preferably 0.01% by mass to 8.0% by mass, and still more preferably 0.03% by mass to 5.0% by mass with respect to the total mass of the photosensitive layer.

(Component: Sensitizer)

The photosensitive layer may include a sensitizer. Examples of the sensitizer include a dialkylaminobenzophenone compound, a pyrazoline compound, an anthracene compound, a coumarin compound, a xanthone compound, a thioxanthone compound, an acridone compound, an oxazole compound, a benzoxazole compound, a thiazole compound, a benzothiazole compound, a triazole compound (for example, 1,2,4-triazole), stilbene compound, a triazine compound, a thiophene compound, a naphthalimide compound, a triarylamine compound, and an aminoacridine compound. It is preferable that the photosensitive layer includes at least one sensitizer selected from the group consisting of a dialkylaminobenzophenone compound, a pyrazoline compound, an anthracene compound, a coumarin compound, a xanthone compound, a thioxanthone compound, an acridone compound, an oxazole compound, a benzoxazole compound, a thiazole compound, a benzothiazole compound, a triazole compound, stilbene compound, a triazine compound, a thiophene compound, a naphthalimide compound, a triarylamine compound, and an aminoacridine compound.

The sensitizer may be used alone, or in combination of two or more kinds thereof.

In a case where the photosensitive layer includes the sensitizer, from the viewpoint of improving sensitivity to the light source and improving a curing rate by balancing the polymerization rate and chain transfer, a content of the sensitizer is preferably 0.01% by mass to 5% by mass, and more preferably 0.05% by mass to 1% by mass with respect to the total mass of the photosensitive layer.

(Component: Ultraviolet Absorber)

The photosensitive layer may include an ultraviolet absorber. With a photosensitive layer including an ultraviolet absorber, a pattern having a low ultraviolet transparency can be obtained.

Examples of the ultraviolet absorber include a benzophenone compound, a benzotriazole compound, a benzoate compound, a salicylate compound, a triazine compound, and a cyanoacrylate compound.

Examples of the benzotriazole compound include 2-(2H-benzotriazol-2-yl)-p-cresol, 2-(2H-benzotriazol-2-yl)-4-6-bis(1-methyl-1-phenyl ethyl)phenol, 2-[5-chloro(2H)-benzotriazol-2-yl]-4-methyl-6-(tert-butyl) phenol, 2-(2H-benzotriazol-yl)-4,6-di-tert-pentylphenol, and 2-(2H-benzotriazol-2-yl)-4-(1,1,3,3-tetramethylbutyl)phenol.

Examples of the triazine compound include 2-(4,6-diphenyl-1,3,5-triazin-2-yl)-5-[(hexyl)oxy]phenol, 2-[4-[(2-hydroxy-3-dodecyl oxypropyl)oxy]-2-hydroxyphenyl]-4,6-bis(2,4-dimethylphenyl)-1,3,5-triazine, 2-[4-[(2-hydroxy-3-tridecyloxypropyl)oxy]-2-hydroxyphenyl]-4,6-bis(2,4-dimethylphenyl)-1,3,5-triazine, and 2,4-bis(2,4-dimethylphenyl)-6-(2-hydroxy-4-isooctyloxyphenyl)-s-triazine.

The photosensitive layer may include one kind or two or more kinds of ultraviolet absorbers.

In a case where the photosensitive layer includes the ultraviolet absorber, a content of the ultraviolet absorber is preferably 0.01% by mass to 5% by mass and more preferably 0.01% by mass to 1% by mass with respect to the total mass of the photosensitive layer.

(Component: Pigment)

The photosensitive layer may include a pigment. The pigment may be appropriately selected according to a desired hue, and can be selected from a black pigment, a white pigment, and a chromatic pigment other than black and white. Among these, in a case of forming a black pattern, a black pigment is suitably selected as the pigment.

As the black pigment, known black pigments (organic pigments, inorganic pigments, or the like) can be appropriately selected as long as the effects of the present disclosure are not impaired. Among these, from the viewpoint of optical density, suitable examples of the black pigment include carbon black, titanium oxide, titanium carbide, iron oxide, titanium oxide, and graphite, and carbon black is particularly preferable. As the carbon black, from the viewpoint of surface electrical resistance, carbon black in which at least a part of a surface is coated with a resin is preferable.

From the viewpoint of dispersion stability, a particle size of the black pigment is preferably 0.001 μm to 0.1 μm and more preferably 0.01 μm to 0.08 μm in terms of number average particle diameter. Here, the particle diameter refers to a diameter of a circle in a case where an area of pigment particles is obtained from a photographic image of the pigment particles taken with an electron microscope and a circle having the same area as the area of the pigment particles is considered, and the number average particle diameter is an average value obtained by determining the particle diameters for any 100 particles and averaging the determined 100 particle diameters.

As the pigment other than the black pigment, white pigments described in paragraphs [0115] and [0114] of JP2005-007765A can be used as the white pigment. Specifically, among the white pigments, as an inorganic pigment, titanium oxide, zinc oxide, lithopone, light calcium carbonate, white carbon, aluminum oxide, aluminum hydroxide, or barium sulfate is preferable, titanium oxide or zinc oxide is more preferable, and titanium oxide is still more preferable. As the inorganic pigment, rutile-type or anatase-type titanium oxide is still more preferable, and rutile-type titanium oxide is particularly preferable. In addition, a surface of titanium oxide may be subjected to a silica treatment, an alumina treatment, a titania treatment, a zirconia treatment, or an organic substance treatment, or may be subjected to two or more treatments thereof. As a result, catalytic activity of titanium oxide is suppressed, and heat resistance, light resistance, and the like are improved. From the viewpoint of reducing a thickness of the photosensitive layer after heating, as the surface treatment of the surface of titanium oxide, at least one of the alumina treatment or the zirconia treatment is preferable, and both alumina treatment and zirconia treatment are particularly preferable.

In addition, in a case where the photosensitive layer is a colored resin layer, from the viewpoint of transferability, it is also preferable that the photosensitive layer further includes a chromatic pigment other than the black pigment and the white pigment. In a case of including a chromatic pigment, from the viewpoint of more excellent dispersibility, a particle size of the chromatic pigment is preferably 0.1 μm or less and more preferably 0.08 μm or less. Examples of the chromatic pigment include Victoria Pure Blue BO (Color Index (hereinafter, C. I.) 42595, Auramine (C. I. 41000), Fat Black HB (C. I. 26150), Monolite Yellow GT (C. I. Pigment Yellow 12), Permanent Yellow GR (C. I. Pigment Yellow 17), Permanent Yellow HR (C. I. Pigment Yellow 83), Permanent Carmine FBB (C. I. Pigment Red 146), Hostaperm Red E5B (C. I. Pigment Violet 19), Permanent Rubine FBH (C. I. Pigment Red 11), Fastel Pink B Supra (C. I. Pigment Red 81), Monastral Fast Blue (C. I. Pigment Blue 15), Monolite Fast Black B (C. I. Pigment Black 1), Carbon, C. I. Pigment Red 97, C. I. Pigment Red 122, C. I. Pigment Red 149, C. I. Pigment Red 168, C. I. Pigment Red 177, C. I. Pigment Red 180, C. I. Pigment Red 192, C. I. Pigment Red 215, C. I. Pigment Green 7, C. I. Pigment Blue 15:1, C. I. Pigment Blue 15:4, C. I. Pigment Blue 22, C. I. Pigment Blue 60, C. I. Pigment Blue 64, and C. I. Pigment Violet 23. Among these, C. I. Pigment Red 177 is preferable.

In a case where the photosensitive layer includes the pigment, a content of the pigment is preferably more than 3% by mass and 40% by mass or less, more preferably more than 3% by mass and 35% by mass or less, still more preferably more than 5% by mass and 35% by mass or less, and particularly preferably 10% by mass to 35% by mass with respect to the total mass of the photosensitive layer.

In a case where the photosensitive layer includes pigments (the white pigment and the chromatic pigment) other than the black pigment, a content of the pigments other than the black pigment is preferably 30% by mass or less, more preferably 1% by mass to 20% by mass, and still more preferably 3% by mass to 15% by mass with respect to the black pigment.

In a case where the photosensitive layer includes the black pigment and the photosensitive layer is formed of a photosensitive composition, the black pigment (preferably, carbon black) is preferably introduced into the photosensitive composition in a form of a pigment dispersion liquid. The dispersion liquid may be prepared by adding a mixture obtained by previously mixing the black pigment and a pigment dispersing agent to an organic solvent (or vehicle) and dispersing it with a disperser. The pigment dispersing agent may be selected according to the pigment and the solvent, and for example, a commercially available dispersing agent can be used. The vehicle refers to a part of a medium in which the pigment is dispersed in a case of being used as the pigment dispersion liquid, is liquid, and includes a binder component which maintains the black pigment in a dispersed state and a solvent component (organic solvent) which dissolves and dilutes the binder component. The disperser is not particularly limited, and examples thereof include known dispersers such as a kneader, a roll mill, an attritor, a super mill, a dissolver, a homomixer, and a sand mill. Further, the pigment may be finely pulverized by a mechanical grinding using frictional force. For the disperser and fine pulverization, the description of “Encyclopedia of Pigments” (First Edition, published by Asakura Shoten, 2000, p. 438, p. 310) can be referred to.

(Component: Impurities)

The photosensitive layer may include a predetermined amount of impurities.

Examples of the impurities include sodium, potassium, magnesium, calcium, iron, manganese, copper, aluminum, titanium, chromium, cobalt, nickel, zinc, tin, halogen, and ions of these. Among these, halide ion, sodium ion, and potassium ion are easily mixed as impurities, so that the following content is preferable.

The content of impurities in the photosensitive layer is preferably 80 ppm or less, more preferably 10 ppm or less, and particularly preferably 2 ppm or less on a mass basis. The content of impurities in the photosensitive layer may be 1 ppb or more or 0.1 ppm or more on a mass basis.

Examples of a method of setting the impurities in the above-described range include selecting a raw material having a low content of impurities as a raw material for the photosensitive layer, preventing the impurities from being mixed in a case of forming the photosensitive layer, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

In the photosensitive layer, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low in each layer. The content of these compounds in the photosensitive layer is preferably 100 ppm or less, more preferably 20 ppm or less, and particularly preferably 4 ppm or less on a mass basis. The lower limit thereof may be 10 ppb or more or 100 ppb or more on a mass basis. The content of these compounds can be suppressed in the same manner as in the above-described metal as impurities. In addition, the compounds can be quantified by a known measurement method.

From the viewpoint of reliability and laminating property, the content of water in the photosensitive layer is preferably 0.01% by mass to 1.0% by mass and more preferably 0.05% by mass to 0.5% by mass.

(Component: Residual Monomer)

The photosensitive layer may include a residual monomer of each constitutional unit in the above-described alkali-soluble resin. From the viewpoint of patterning properties and reliability, a content of the residual monomer is preferably 5,000 ppm by mass or less, more preferably 2,000 ppm by mass or less, and still more preferably 500 ppm by mass or less with respect to the total mass of the alkali-soluble resin. The lower limit is not particularly limited, but is preferably 1 ppm by mass or more and more preferably 10 ppm by mass or more.

From the viewpoint of patterning properties and reliability, the residual monomer of each constitutional unit in the alkali-soluble resin is preferably 3,000 ppm by mass or less, more preferably 600 ppm by mass or less, and still more preferably 100 ppm by mass or less with respect to the total mass of the photosensitive layer. The lower limit is not particularly limited, but is preferably 0.1 ppm by mass or more and more preferably 1 ppm by mass or more.

It is preferable that the amount of residual monomer of the monomer in a case of synthesizing the alkali-soluble resin by the polymer reaction is also within the above-described range. For example, in a case where glycidyl acrylate is reacted with a carboxylic acid side chain to synthesize the alkali-soluble resin, the content of glycidyl acrylate is preferably within the above-described range.

The amount of residual monomers can be measured by a known method such as liquid chromatography and gas chromatography.

(Component: Other Components)

The photosensitive layer may include other components. Examples of the other components include a colorant, an antioxidant, and particles (for example, metal oxide particles). In addition, examples of the other components also include other additives described in paragraphs [0058] to [0071] of JP2000-310706A.

As the particles, metal oxide particles are preferable. The metal of the metal oxide particles also includes semimetal such as B, Si, Ge, As, Sb, or Te.

From the viewpoint of transparency of the cured film, for example, an average primary particle diameter of the particles is preferably 1 to 200 nm and more preferably 3 to 80 nm. The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

In a case where the photosensitive layer includes the particles, the photosensitive layer may include only one kind of particles, or may include two or more kinds of particles having different metal types, sizes, and the like.

It is preferable that the photosensitive layer does not include the particles, or in a case where the photosensitive layer includes the particles, a content of the particles is more than 0% by mass and 35% by mass or less with respect to the total mass of the photosensitive layer; it is more preferable that the photosensitive layer does not include the particles, or in a case where the photosensitive layer includes the particles, a content of the particles is more than 0% by mass and 10% by mass or less with respect to the total mass of the photosensitive layer; it is still more preferable that the photosensitive layer does not include the particles, or in a case where the photosensitive layer includes the particles, a content of the particles is more than 0% by mass and 5% by mass or less with respect to the total mass of the photosensitive layer; it is even more preferable that the photosensitive layer does not include the particles, or in a case where the photosensitive layer includes the particles, a content of the particles is more than 0% by mass and 1% by mass or less with respect to the total mass of the photosensitive layer; and it is particularly preferable that the photosensitive layer does not include the particles.

Examples of the antioxidant include 3-pyrazolidones such as 1-phenyl-3-pyrazolidone (another name; phenidone), 1-phenyl-4,4-dimethyl-3-pyrazolidone, and 1-phenyl-4-methyl-4-hydroxymethyl-3-pyrazolidone; polyhydroxybenzenes such as hydroquinone, catechol, pyrogallol, methylhydroquinone, and chlorohydroquinone; paramethylaminophenol, paraaminophenol, parahydroxyphenylglycine, and paraphenylenediamine. Among these, as the antioxidant, from the viewpoint that the effects of the present disclosure are more excellent, 3-pyrazolidones are preferable, and 1-phenyl-3-pyrazolidone is more preferable. In a case where the photosensitive layer includes the antioxidant, a content of the antioxidant is preferably 0.001% by mass or more, more preferably 0.005% by mass or more, and still more preferably 0.01% by mass or more with respect to the total mass of the photosensitive layer. The upper limit is not particularly limited, and is preferably 1% by mass or less.

(Thickness)

From the viewpoint of resolution, a thickness of the photosensitive layer is preferably 30 μm or less, more preferably 20 μm or less, still more preferably 15 μm or less, particularly preferably 10 μm or less, and most preferably 5.0 μm or less. From the viewpoint that hardness of a film obtained by curing the photosensitive layer is excellent, the lower limit is preferably 0.60 μm or more and more preferably 1.5 μm or more. For example, the thickness of the photosensitive layer is obtained as an average value of 5 random points measured by cross-sectional observation with a scanning electron microscope (SEM).

(Other Characteristics)

A refractive index of the photosensitive layer is preferably 1.41 to 1.59 and more preferably 1.47 to 1.56

The photosensitive layer is preferably achromatic. Specifically, in CIE1976 (L*, a*, b*) color space of the total reflection (incidence angle: 8°, light source: D-65 (visual field: 2°)), the L* value is preferably 10 to 90, the a* value is preferably −1.0 to 1.0, and the b* value is preferably −1.0 to 1.0.

A pattern obtained by curing the photosensitive layer (cured film of the photosensitive layer) is preferably achromatic. Specifically, in CIE1976 (L*, a*, b*) color space, the total reflection (incidence angle: 8°, light source: D-65 (visual field: 2°)) preferably has a pattern L* value of 10 to 90, preferably has a pattern a*value of −1.0 to 1.0, and preferably has a pattern b* value of −1.0 to 1.0.

A visible light transmittance of the photosensitive layer at a film thickness of approximately 1.0 μm is preferably 80% or more, more preferably 90% or more, and most preferably 95% or more. As the visible light transmittance, it is preferable that an average transmittance at a wavelength of 400 nm to 800 nm, the minimum value of the transmittance at a wavelength of 400 nm to 800 nm, and a transmittance at a wavelength of 400 nm all satisfy the above. Examples of a preferred value of the transmittance include 87%, 92%, and 98%. The same applies to a transmittance of the cured film of the photosensitive layer at a film thickness of approximately 1 μm.

From the viewpoint of rust preventive property of electrode or wiring line, and viewpoint of device reliability, a moisture permeability of the pattern obtained by curing the photosensitive layer (cured film of the photosensitive layer) at a film thickness of 40 μm is preferably 500 g/m²·24 hr, more preferably 300 g/m²·24 hr, and still more preferably 100 g/m²·24 hr. The moisture permeability is measured with a cured film obtained by curing the photosensitive layer by exposing the photosensitive layer with i-rays at an exposure amount of 300 mJ/cm², and then performing post-baking at 145° C. for 30 minutes. The moisture permeability is measured according to a cup method of JIS Z0208. It is preferable that the above-described moisture permeability is as above under any test conditions of temperature 40° C. and humidity 90%, temperature 65° C. and humidity 90%, or temperature 80° C. and humidity 95%. Examples of a specific preferred numerical value include 80 g/m²·24 hr, 150 g/m²·24 hr, and 220 g/m²·24 hr.

From the viewpoint of suppressing residue during development, a dissolution rate of the photosensitive layer in a 1.0% sodium carbonate aqueous solution is preferably 0.01 μm/sec or more, more preferably 0.10 μm/sec or more, and still more preferably 0.20 μm/sec or more. From the viewpoint of edge shape of the pattern, it is preferable to be 5.0 μm/sec or less, more preferable to be 4.0 μm/sec or less, and still more preferable to be 3.0 μm/sec or less. Examples of a specific preferred numerical value include 1.8 μm/sec, 1.0 μm/sec, and 0.7 μm/sec. The dissolution rate of the photosensitive layer in a 1.0% by mass sodium carbonate aqueous solution per unit time is measured as follows. A photosensitive layer (within a film thickness of 1.0 to 10 μm) formed on a glass substrate, from which the solvent has been sufficiently removed, is subjected to a shower development with a 1.0% by mass sodium carbonate aqueous solution at 25° C. until the photosensitive layer is dissolved completely (however, the maximum time is 2 minutes). The dissolution rate of the photosensitive layer is obtained by dividing the film thickness of the photosensitive layer by the time required for the photosensitive layer to dissolve completely. In a case where the photosensitive layer is not dissolved completely in 2 minutes, the dissolution rate of the photosensitive layer is calculated in the same manner as above, from the amount of change in film thickness up to 2 minutes. For development, a shower nozzle of ¼ MiNJJX030PP manufactured by H.IKEUCHI Co., Ltd. is used, and a spraying pressure of the shower is set to 0.08 MPa. Under the above-described conditions, a shower flow rate per unit time is set to 1,800 mL/min.

A dissolution rate of the cured film (within a film thickness of 1.0 to 10 μm) of the photosensitive layer in a 1.0% sodium carbonate aqueous solution is preferably 3.0 μm/sec or less, more preferably 2.0 μm/sec or less, still more preferably 1.0 μm/sec or less, and most preferably 0.2 μm/sec or less. The cured film of the photosensitive layer is a film obtained by exposing the photosensitive layer with i-rays at an exposure amount of 300 mJ/cm². Examples of a specific preferred numerical value include 0.8 μm/sec, 0.2 μm/sec, and 0.001 μm/sec.

From the viewpoint of improving pattern formability, a swelling ratio of the photosensitive layer after exposure with respect to a 1.0% by mass sodium carbonate aqueous solution is preferably 100% or less, more preferably 50% or less, and still more preferably 30% or less. The swelling ratio of the photosensitive layer after exposure with respect to a 1.0% by mass sodium carbonate aqueous solution is measured as follows. A photosensitive layer (within a film thickness of 1.0 to 10 μm) formed on a glass substrate, from which the solvent has been sufficiently removed, is exposed at an exposure amount of 500 mJ/cm² (i-ray measurement) with an ultra-high pressure mercury lamp. The glass substrate is immersed in a 1.0% by mass sodium carbonate aqueous solution at 25° C., and the film thickness is measured after 30 seconds. Then, an increased proportion of the film thickness after immersion to the film thickness before immersion is calculated. Examples of a specific preferred numerical value include 4%, 13%, and 25%.

From the viewpoint of pattern formability, the number of foreign substances having a diameter of 1.0 μm or more in the photosensitive layer is preferably 10 pieces/mm² or less, and more preferably 5 pieces/mm² or less. The number of foreign substances is measured as follows. Any 5 regions (1 mm×1 mm) on a surface of the photosensitive layer are visually observed from a normal direction of the surface of the photosensitive layer with an optical microscope, the number of foreign substances having a diameter of 1.0 μm or more in each region is measured, and the values are arithmetically averaged to calculate the number of foreign substances. Examples of a specific preferred numerical value include 0 pieces/mm², 1 pieces/mm², 4 pieces/mm², and 8 pieces/mm².

From the viewpoint of suppressing generation of aggregates during development, a haze of a solution obtained by dissolving 1.0 cm³ of the photosensitive layer in 1.0 liter of a 1.0% by mass sodium carbonate aqueous solution at 30° C. is preferably 60% or less, more preferably 30% or less, still more preferably 10% or less, and most preferably 1% or less. The haze is measured as follows. First, a 1.0% by mass sodium carbonate aqueous solution is prepared, and a liquid temperature is adjusted to 30° C. 1.0 cm³ of the photosensitive layer is added to 1.0 L of the sodium carbonate aqueous solution. The solution is stirred at 30° C. for 4 hours, being careful not to mix air bubbles. After stirring, the haze of the solution in which the photosensitive layer is dissolved is measured. The haze is measured using a haze meter (product name “NDH4000”, manufactured by Nippon Denshoku Industries Co., Ltd.), a liquid measuring unit, and a liquid measuring cell having an optical path length of 20 mm. Examples of a specific preferred numerical value include 0.4%, 1.0%, 9%, and 24%.

[Protective Film]

The transfer film may include a protective film. As the protective film, a resin film having heat resistance and solvent resistance can be used, and examples thereof include polyolefin films such as a polypropylene film and a polyethylene film, polyester films such as a polyethylene terephthalate film, polycarbonate films, and polystyrene films. In addition, as the protective film, a resin film formed of the same material as in the above-described temporary support may be used. Among these, as the protective film, a polyolefin film is preferable, a polypropylene film or a polyethylene film is more preferable, and a polyethylene film is still more preferable.

A thickness of the protective film is preferably 1 μm to 100 μm, more preferably 5 μm to 50 μm, still more preferably 5 μm to 40 μm, and particularly preferably 15 μm to 30 μm. From the viewpoint of excellent mechanical hardness, the thickness of the protective film is preferably 1 μm or more, and from the viewpoint of relatively low cost, the thickness of the protective film is preferably 100 μm or less.

In addition, in the protective film, it is preferable that the number of fisheyes with a diameter of 80 μm or more in the protective film is 5 pieces/m² or less. The “fisheye” means that, in a case where a material is hot-melted, kneaded, extruded, biaxially stretched, cast or the like to produce a film, foreign substances, undissolved substances, oxidatively deteriorated substances, and the like of the material are incorporated into the film.

The number of particles having a diameter of 3 μm or more included in the protective film is preferably 30 particles/mm² or less, more preferably 10 particles/mm² or less, and still more preferably 5 particles/mm² or less. It is possible to suppress defects caused by ruggedness due to the particles included in the protective film being transferred to the photosensitive layer or a conductive layer.

From the viewpoint of imparting take-up property, in the protective film, an arithmetic average roughness Ra on a surface opposite to a surface in contact with the transfer layer is preferably 0.01 μm or more, more preferably 0.02 μm or more, and still more preferably 0.03 μm or more. On the other hand, it is preferable to be less than 0.50 μm, more preferable to be 0.40 μm or less, and still more preferable to be 0.30 μm or less.

From the viewpoint of suppressing defects during transfer, in the protective film, the surface roughness Ra on the surface in contact with the transfer layer is preferably 0.01 μm or more, more preferably 0.02 μm or more, and still more preferably 0.03 μm or more. On the other hand, it is preferable to be less than 0.50 μm, more preferable to be 0.40 μm or less, and still more preferable to be 0.30 μm or less.

[Relationship Between Temporary Support, Photosensitive Layer, and Protective Film]

It is preferable that a breaking elongation of the cured film obtained by curing the photosensitive layer at 120° C. is 15% or more, an arithmetic average roughness Ra of a surface of the temporary support on the photosensitive layer side is 50 nm or less, and an arithmetic average roughness Ra of a surface of the protective film on the photosensitive layer side is 150 nm or less.

It is preferable to satisfy the following expression (1).

X×Y<1500 Expression (1)

Here, in Expression (1), X represents a value (%) of the breaking elongation of the cured film obtained by curing the photosensitive layer at 120° C., and Y represents a value (nm) of the arithmetic average roughness Ra of the surface of the temporary support on the photosensitive layer side. The X×Y is more preferably 750 or less. Examples of a specific numerical value of the X include 18%, 25%, 30%, and 35%. Examples of a specific numerical value of the Y include 4 nm, 8 nm, 15 nm, and 30 nm. Examples of a specific numerical value of the X×Y include 150, 200, 300, 360, and 900.

It is preferable that the above-described breaking elongation at 120° C. is twice or more larger than a breaking elongation of the cured film obtained by curing the photosensitive layer at 23° C.

The breaking elongation is measured by a tensile test with a cured film which is obtained by exposing a photosensitive layer having a thickness of 20 μm at an exposure amount of 120 mJ/cm² with an ultra-high pressure mercury lamp to be cured, further exposing at an exposure amount of 400 mJ/cm² with a high pressure mercury lamp, and heating at 145° C. for 30 minutes.

It is preferable to satisfy the following expression (2).

Y≤Z Expression (2)

Here, in Expression (2), Y represents the value (nm) of the arithmetic average roughness Ra of the surface of the temporary support on the photosensitive layer side, and Z represents a value (nm) of the arithmetic average roughness Ra of the surface of the protective film on the photosensitive layer side.

[Manufacturing Method of Transfer Film]

As long as a target transfer film is obtained, a manufacturing method of the transfer film is not limited. The manufacturing method of the transfer film preferably includes applying a photosensitive composition to the temporary support to form a coating film, and drying the coating film to form a photosensitive layer. According to the above-described method, a transfer film including the temporary support and the photosensitive layer is obtained. A transfer film further including the protective film may be manufactured by pressure-bonding the protective film to the photosensitive layer. The manufacturing method of the transfer film may include forming the photosensitive layer and the temporary support on the protective film in this order. In the manufacturing method of the transfer film, a roll-shaped transfer film may be manufactured by winding. The transfer film may be stored in a roll form. The roll-shaped transfer film is provided as it is in a bonding step described later with a roll-to-roll method.

Components of the photosensitive composition are determined according to components of a target photosensitive layer. The photosensitive composition may include a solvent in addition to the above-described components constituting the photosensitive layer. The solvent is preferably an organic solvent. Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol. In addition, as the solvent, an organic solvent (high-boiling-point solvent) having a boiling point of 180° C. to 250° C. can also be used, as necessary.

The solvent may be used alone or in combination of two or more kinds thereof.

The total solid content of the photosensitive composition is preferably 5% by mass to 80% by mass, more preferably 5% by mass to 40% by mass, and still more preferably 5% by mass to 30% by mass with respect to the total mass of the photosensitive composition. That is, a content of the solvent in the photosensitive composition is preferably 20% by mass to 95% by mass, more preferably 60% by mass to 95% by mass, and still more preferably 70% by mass to 95% by mass with respect to the total mass of the photosensitive composition.

For example, from the viewpoint of coating properties, a viscosity of the photosensitive composition at 25° C. is preferably 1 mPa·s to 50 mPa·s, more preferably 2 mPa·s to 40 mPa·s, and still more preferably 3 mPa·s to 30 mPa·s. The viscosity is measured using a viscometer. As the viscometer, for example, a viscometer (product name: VISCOMETER TV-22) manufactured by Toki Sangyo Co. Ltd. can be suitably used. However, the viscometer is not limited to the above-described viscometer.

For example, from the viewpoint of coating properties, a surface tension of the photosensitive composition at 25° C. is preferably 5 mN/m to 100 mN/m, more preferably 10 mN/m to 80 mN/m, and still more preferably 15 mN/m to 40 mN/m. The surface tension is measured using a tensiometer. As the tensiometer, for example, a tensiometer (product name: Automatic Surface Tensiometer CBVP-Z) manufactured by Kyowa Interface Science Co., Ltd. can be suitably used. However, the tensiometer is not limited to the above-described tensiometer.

Examples of a method for applying the photosensitive composition include a printing method, a spray coating method, a roll coating method, a bar coating method, a curtain coating method, a spin coating method, and a die coating method (that is, a slit coating method).

As a method for drying the coating film of the photosensitive composition, heat drying or vacuum drying is preferable. In the present disclosure, the “drying” means removing at least a part of the solvent included in the composition. Examples of the drying method include natural drying, heating drying, and drying under reduced pressure. The above-described methods can be adopted alone or in combination of two or more thereof.

The drying temperature is preferably 80° C. or higher and more preferably 90° C. or higher. In addition, the upper limit value thereof is preferably 130° C. or lower and more preferably 120° C. or lower. The drying can be performed by continuously changing the temperature.

The drying time is preferably 20 seconds or more, more preferably 40 seconds or more, and still more preferably 60 seconds or more. In addition, the upper limit value thereof is not particularly limited, but is preferably 600 seconds or less, and more preferably 300 seconds or less.

A method of bonding the protective film and the photosensitive layer is not particularly limited, and a known method can be mentioned. Examples of an apparatus for bonding the protective film and the photosensitive layer include known laminators such as a vacuum laminator and an auto-cut laminator. It is preferable that the laminator is equipped with any heatable roller such as a rubber roller and can perform pressing and heating.

[Use of Transfer Film]

The transfer film is used for manufacturing a base material for a display panel. The transfer film is preferably used in manufacturing of a base material for a display panel described in the section of “Base material for display panel” described below. Preferred aspects of the usage method of the transfer film are described in each section of “Base material for display panel” and “Display panel” described below.

<Base Material for Display Panel>

Hereinafter, a base material for a display panel according to one aspect of the present disclosure will be described.

[Partition Wall]

The base material for a display panel includes a partition wall separating pixels. In the present disclosure, the “partition wall separating pixels” means a partition wall which has a function and purpose of separating pixels from each other. That is, unless an assumption that the base material for a display panel includes pixels is clearly stated, the term “partition wall separating pixels” is used not only for a partition wall which actually separates the pixels, but also for a partition wall which is later placed between the pixels in order to separate the pixels.

A softening temperature of the partition wall is preferably 300° C. or higher, more preferably 350° C. or higher, and still more preferably 400° C. or higher. In a case where the softening temperature of the partition wall is 300° C. or higher, thermal stability of the partition wall is improved. By improving the thermal stability of the partition wall, collapse and deformation of the partition wall can be reduced. Therefore, according to the above-described embodiment, a base material for a display panel, including a partition wall which is less likely to collapse and deform, is provided. In addition, in a case where the softening temperature of the partition wall is 300° C. or higher, even in a case where an aspect ratio of the partition wall is large, the partition wall is less likely to collapse or deform. The upper limit of the softening temperature of the partition wall is not limited. The softening temperature of the partition wall may be 800° C. or lower, 700° C. or lower, 600° C. or lower, or 500° C. or lower. The softening temperature of the partition wall is measured by the method according to the above-described measuring method of “softening temperature of the photosensitive layer after exposure”. For example, the softening temperature of the partition wall is adjusted by softening temperatures of components (preferably, an organic resin) of the partition wall. For example, as the softening temperature of the organic resin increases, the softening temperature of the partition wall tends to increase. In a case where the photosensitive layer is used as a material of the partition wall, the softening temperature of the partition wall may be adjusted by the composition of the photosensitive layer described above. In a case where the negative photosensitive layer is used as a material of the partition wall, the softening temperature of the partition wall may be adjusted by a degree of curing of the negative photosensitive layer.

An elastic modulus of the partition wall is preferably 2 GPa or more, more preferably 3 GPa or more, still more preferably 4 GPa or more, and particularly preferably 5 GPa or more. In a case where the elastic modulus of the partition wall is 2 GPa or more, the collapse and deformation of the partition wall is reduced. In addition, in a case where the elastic modulus of the partition wall is 5 GPa or more, even in a case where an aspect ratio of the partition wall is large, the partition wall is less likely to collapse or deform. From the viewpoint of suppressing cracks of a cured product, the elastic modulus of the partition wall is preferably 10 GPa or less, more preferably 9 GPa or less, and still more preferably 8 GPa or less. In the present disclosure, the “elastic modulus of the partition wall” means an elastic modulus of the partition wall at 25° C. The elastic modulus of the partition wall is measured by an atomic force microscope (AFM). The specific procedure is as follows. A measurement is performed in a QNM mode with an atomic force microscope (for example, AFM Dimension Icon manufactured by Bruker Corporation). As a probe, for example, RTESPA-150 (150 kHz, 5 N/m) is used. A total of 5 visual fields are measured at a 2 μm angle per one visual field, a total of 50 force curves are measured at 10 points per one visual field, and the elastic modulus is calculated from an inclination of a return force curve (region of 20% to 90% of the maximum load) using the Hertz contact theory. Specific examples of AFM probe calibration are as follows. A warping sensitivity is calculated from an inclination of a force curve by measuring a force curve of a quartz substrate in advance. A spring constant is calculated by measuring a thermal fluctuation of the probe. For example, the spring constant is calculated with the Thermal Tune method included in the software of AFM manufactured by Bruker Corporation. A curvature of a tip is calculated by measuring a shape of a sample for calibrating tip curvature (RM-12M: Ti Roughness Sample) and using, for example, an image analysis mode (Tip Qualification) included in the software of AFM manufactured by Bruker Corporation. For example, the elastic modulus of the partition wall is adjusted by elastic modulus of components (preferably, an organic resin) of the partition wall. For example, as the elastic modulus of the organic resin increases, the elastic modulus of the partition wall tends to increase. In a case where the photosensitive layer is used as a material of the partition wall, the elastic modulus of the partition wall may be adjusted by the composition of the photosensitive layer described above. In a case where the negative photosensitive layer is used as a material of the partition wall, the elastic modulus of the partition wall may be adjusted by a degree of curing of the negative photosensitive layer.

From the viewpoint of reducing the collapse and deformation of the partition wall, a double bond value of the partition wall is preferably 2.0 mmol/g or less, more preferably 1.5 mmol/g or less, and still more preferably 1.0 mmol/g or less. The double bond value of the partition wall is preferably 0.01 mmol/g or more, more preferably 0.05 mmol/g or more, and still more preferably 0.08 mmol/g or more. The double bond value of the partition wall is measured by Fourier transform infrared spectroscopy (FT-IR). For example, the double bond value of the partition wall is adjusted by the composition of the partition wall and the material of the partition wall. In a case where the negative photosensitive layer is used as a material of the partition wall, the double bond value of the partition wall may be adjusted by a degree of curing of the negative photosensitive layer.

From the viewpoint of solvent resistance, a solubility of the partition wall in propylene glycol monomethyl ether acetate is preferably 0.1 g/L or less, more preferably 0.05 g/L or less, and still more preferably 0.01 g/L or less. The lower limit of the solubility of the partition wall in propylene glycol monomethyl ether acetate may be 0 g/L. The solubility is measured using propylene glycol monomethyl ether acetate at 25° C. For example, the solubility of the partition wall is adjusted by the composition of the partition wall and the material of the partition wall. In a case where the negative photosensitive layer is used as a material of the partition wall, the solubility of the partition wall may be adjusted by a degree of curing of the negative photosensitive layer.

From the viewpoint of light shielding properties, an optical density of the partition wall is preferably 2.5 or more, more preferably 3.0 or more, and still more preferably 3.5 or more. The upper limit of the optical density of the partition wall may be 4.0, 4.5, or 5. The optical density of the partition wall is measured by a colorimeter.

From the viewpoint of light shielding properties and prevention of color mixing, a width of the partition wall is preferably 1 μm or more, more preferably 2 μm or more, and still more preferably 3 μm or more. From the viewpoint of high resolution (for example, increase in the number of pixels), the width of the partition wall is preferably 10 μm or less, more preferably 8 μm or less, and still more preferably 6 μm or less.

From the viewpoint of high brightness (for example, increase in filling amount of the pixels), a height of the partition wall is preferably 1 μm or more, more preferably 5 μm or more, and still more preferably 10 nm or more. Further, the height of the partition wall is preferably 15 μm or more, and more preferably 20 μm or more. From the viewpoint of rectangularity of a shape of the partition wall, the height of the partition wall is preferably 35 μm or less, more preferably 30 μm or less, and still more preferably 25 mil or less.

From the viewpoint of high brightness and high resolution, a ratio of the height of the partition wall to the width of the partition wall, that is, an aspect ratio of the partition wall is preferably 1 or more, more preferably 3 or more, and still more preferably 5 or more. From the viewpoint of reducing the collapse of the partition wall, the aspect ratio of the partition wall is preferably 10 or less, more preferably 9 or less, and still more preferably 8 or less. In a case where the width of the partition wall is 1 μm or more, it is preferable that the aspect ratio of the partition wall is set in the above-described range.

Examples of a cross-sectional shape of the partition wall include a square, a rectangle, and a trapezoid.

The partition wall may have a monolayer structure or a multilayer structure.

The partition wall is preferably a composition including an organic resin. The composition including an organic resin can easily adjust the characteristics of the partition wall. In addition, the composition including an organic resin has excellent chemical stability, so that a fine partition wall can be formed. The organic resin includes a known organic resin. Examples of the organic resin include the binder polymers described in the section of “Photosensitive layer” described above. Examples of the organic resin include the polymers of the polymerizable compound described in the section of “Photosensitive layer” described above. The composition may include other components in addition to the organic resin. Examples of the other components include the components (excluding the binder polymer) described in the section of “Photosensitive layer” described above. Specific examples of the other components are shown below. The composition may include one kind or two or more kinds of components selected from the components shown below. However, the types of the other components are not limited to the following specific examples.

The composition may include a nitrogen-containing compound. The type of the nitrogen-containing compound is not limited. The nitrogen-containing compound may be selected from the components (for example, the polymerization initiator, the sensitizer, and the polymerization inhibitor) of the photosensitive layer described in the section of “Photosensitive layer” described above.

The composition may include a chlorine compound. The type of the chlorine compound is not particularly limited. The chlorine compound may be selected from the components (for example, the polymerization initiator) of the photosensitive layer described in the section of “Photosensitive layer” described above.

The composition may include at least one compound selected from the group consisting of a compound having an oxime ester structure, a compound having an α-hydroxyalkylphenone structure, a compound having an acylphosphine oxide structure, and a compound having a triarylimidazole structure. Examples of the above-described compound include the polymerization initiators described in the section of “Photosensitive layer” described above.

The composition may include at least one compound selected from the group consisting of a dialkylaminobenzophenone compound, a pyrazoline compound, an anthracene compound, a coumarin compound, a xanthone compound, a thioxanthone compound, an acridone compound, an oxazole compound, a benzoxazole compound, a thiazole compound, a benzothiazole compound, a triazole compound, stilbene compound, a triazine compound, a thiophene compound, a naphthalimide compound, a triarylamine compound, and an aminoacridine compound. Examples of the above-described compound include the sensitizers described in the section of “Photosensitive layer” described above.

The composition may include a compound having at least one polymerizable group selected from the group consisting of a vinyl group, an acryloyl group, a methacryloyl group, a styryl group, and a maleimide group. Examples of the above-described compound include the polymerizable compounds described in the section of “Photosensitive layer” described above.

The composition may include an ultraviolet absorber. The ultraviolet absorber can reduce a proportion of ultraviolet rays passing through the partition wall, and for example, can prevent unintended color mixing in use of the display panel. Examples of the ultraviolet absorber include the ultraviolet absorbers described in the section of “Photosensitive layer” described above.

The composition may include a pigment. Examples of the pigment include the pigment described in the section of “Photosensitive layer” described above.

[Other Constituent Elements]

The base material for a display panel may include other constituent elements in addition to the partition wall. Examples of the other constituent elements include a light shielding film, a pixel, a light emitting element, and a bonding base material. However, the other constituent elements are not limited to the above-described specific examples, and may be selected from known constituent elements of a display panel.

The base material for a display panel preferably includes a light shielding film with which at least a part of a surface of the partition wall is coated. The light shielding film has a property of absorbing or reflecting light. The light shielding film may have a property of absorbing and reflecting light. The light shielding film can contribute to improvement of luminous efficacy of the display panel and prevention of color mixing. In a case where the base material for a display panel includes the above-described light shielding film, another layer may be disposed between the partition wall and the light shielding film.

Examples of a component of the light shielding film include metal. Examples of the metal include aluminum and nickel. The metal may be an alloy. Examples of the alloy include an aluminum alloy and a nickel alloy.

From the viewpoint of light shielding properties, a thickness of the light shielding film is preferably 10 nm or more, more preferably 50 nm or more, and still more preferably 100 nm or more. From the viewpoint of increase in filling amount of the pixels, the thickness of the light shielding film is preferably 500 nm or less, more preferably 300 nm or less, and still more preferably 200 nm or less.

Examples of a method for forming the light shielding film include sputtering, vapor deposition, and electroless plating.

The base material for a display panel may include a pixel. Specifically, the base material for a display panel may include a plurality of pixels and the partition wall separating pixels in the plurality of pixels. In the present disclosure, the “pixel” means the smallest unit for displaying a color in a displayed image. The term “pixel” includes a monochromatic pixel. For example, in a method of expressing a specific color by combining a plurality of colors (for example, red, green, and blue), a region for displaying one color of the plurality of colors may be referred to as the “pixel”.

Examples of colors displayed by the pixels include red, green, blue. In other words, examples of the pixels include a pixel displaying red, a pixel displaying green, and a pixel displaying blue. However, the colors displayed by the pixels are not limited to the above-described specific examples. For example, the colors displayed by the pixels are determined according to a method expressing the colors in the displayed image.

Examples of a component of the pixel include a phosphor described later. Examples of a component of the pixel also include a quantum dot described later.

The type of the constituent element of the pixel is not limited. The constituent element of the pixel is determined, for example, according to a method of displaying a target color. Examples of the constituent element of the pixel include a wavelength conversion layer and a light emitting element. The pixel may include other constituent elements as needed. Preferred embodiments for the constituent element and combination of the pixel are shown below.
(1) pixel includes a wavelength conversion layer.
(2) pixel includes a light emitting element and a wavelength conversion layer.
(3) pixel includes a light emitting element which emits visible light.

According to the embodiment shown in (1) above, the pixel can display a desired color, for example, by converting a wavelength of light emitted from a light source (for example, a light emitting element) into a specific wavelength by the wavelength conversion layer. According to the embodiment shown in (2) above, the pixel can display a desired color, for example, by converting a wavelength of light emitted from the light emitting element into a specific wavelength by the wavelength conversion layer. According to the embodiment shown in (3) above, the pixel can display a desired color, for example, with the visible light emitted from the light emitting element.

The wavelength conversion layer can convert a wavelength of light incident on the wavelength conversion layer. The wavelength conversion layer may absorb or reflect a part of the light incident on the wavelength conversion layer. The wavelength conversion layer may emit fluorescence. That is, the wavelength conversion layer may be a fluorescent light emitting layer. The wavelength conversion layer may absorb light having a wavelength of 500 nm or less and emit light having a wavelength longer than the absorption wavelength. The wavelength conversion layer may convert ultraviolet rays into visible light.

The wavelength conversion layer preferably includes a wavelength conversion substance. The wavelength conversion layer may include one kind or two or more kinds of wavelength conversion substances. Examples of the wavelength conversion substance include a phosphor. The wavelength conversion layer including a phosphor can emit fluorescence by absorbing light. The phosphor includes a known phosphor. Examples of the phosphor include an organic phosphor and an inorganic phosphor. Examples of the wavelength conversion substance also include phosphors described in paragraphs [0069] to [0078] of WO2018/186300A. The contents of the above-described documents are incorporated in the present specification by reference. Examples of the wavelength conversion substance also include a quantum dot.

Examples of the organic phosphor include a pyrromethene-based compound, a perylene-based compound, a porphyrin-based compound, an oxazine-based compound, and a pyrazine-based compound.

Examples of the inorganic phosphor include a yttrium-aluminum-garnet (YAG)-based phosphor, a terbium-aluminum-garnet (TAG)-based phosphor, a sialon-based phosphor. Examples of the inorganic phosphor include Y₂O₃:Eu, YVO₄:Eu, (Y,Gd)BO₃:Eu, Y(P,V)O₄:Eu, Y₂O₃S:Eu, Zn₂GeO₂:Mn, BaAl₁₂O₁₉:Mn, Zn₂SiO₄:Mn, Zn₂SiO₄:Mn,As, Y₃Al₅O₁₂:Ce, Gd₂O₂S:Tb, BaMgAl₁₄.O₂₃:Eu, BaMgAl₁₆O₂₇:Eu, BaMg₂Al₁₄O₂₄:Eu, and Y₂SiO₃:Ce.

Examples of a component of the quantum dot include Si, Ge, Sn, Se, Te, B, C, P, BN, BP, BAs, AlN, AlP, AlAs, AlSb, GaN, GaP, GaAs, GaSb, InN, InP, InAs, InSb, ZnO, ZnS, ZnSe, ZnTe, CdS, CdSe, CdSeZn, CdTe, HgS, HgSe, HgTe, BeS, BeSe, BeTe, MgS, MgSe, GeS, GeSe, GeTe, SnS, SnSe, SnTe, PbO, PbS, PbSe, PbTe, CuF, CuCl, CuBr, CuI, Si₃N₄, Ge₃N₄, and Al₂O₃. The quantum dot may have a core-shell structure. Examples of the quantum dot also include quantum dots described in paragraphs [0070] to [0078] of WO2018/186300A. The contents of the above-described documents are incorporated in the present specification by reference.

Examples of a form of the wavelength conversion substance include particles. Examples of the particles include spherical particles, columnar particles, plate-shaped particles, and amorphous particles.

The wavelength conversion layer may include other components. Examples of the other components include a polymer. The polymer can function as a binder. Examples of the polymer include polyvinyl acetate, polyvinyl alcohol, ethyl cellulose, methyl cellulose, polyethylene, silicone resins (for example, polymethylsiloxane and polymethylphenylsiloxane), polystyrene, a copolymer of butadiene and styrene, polystyrene, polyvinylpyrrolidone, polyamide, high-molecular-weight polyether, a copolymer of ethylene oxide and propylene oxide, polyacrylamide, and an acrylic resin.

The wavelength conversion layer is manufactured, for example, by using a composition including the wavelength conversion substance. A composition of the composition including the wavelength conversion substance is determined, for example, according to a composition of a wavelength conversion layer. The composition including the wavelength conversion substance may be a resist material. Usually, the wavelength conversion layer is manufactured by introducing the composition into a space defined by the partition wall. The wavelength conversion layer may be manufactured by introducing the composition into a space defined by the partition wall, and then curing the composition. The wavelength conversion layer may be manufactured by introducing the composition into a space defined by the partition wall, and then performing exposure and development of the composition.

The base material for a display panel may include a light emitting element. As described above, the light emitting element may be a part of the pixel. The light emitting element may be a constituent element different from the pixel. Examples of the latter embodiment include a base material for a display panel including a plurality of pixels, the partition wall separating pixels in the plurality of pixels, and a light emitting element. The number of light emitting elements in the base material for a display panel may be 1 or 2 or more.

The type of the light emitting element is not limited. Examples of the light emitting element include a light emitting diode (LED). The light emitting diode (LED) may be a light emitting element referred to as a micro LED or a mini LED. The light emitting diode (LED) may be an organic light emitting diode (OLED).

Examples of the light emitted from the light emitting element include ultraviolet rays and visible light. Examples of the light emitting element which emits visible light include a red light emitting element, a green light emitting element, and a blue light emitting element. The light emitting element may be a light emitting element which emits ultraviolet rays or blue light. The light emitting element may be a light emitting element which emits light having a wavelength of 500 nm or less. The light emitting element may be a light emitting element which emits light having a wavelength of 10 nm to 500 nm. A light emitting element which emits light having a short wavelength is suitable for use in combination with the wavelength conversion layer (preferably, the fluorescent light emitting layer).

The base material for a display panel may include a bonding base material. The bonding base material can improve adhesiveness between the constituent elements. The bonding base material or a material of the bonding base material may have a property of exhibiting adhesiveness or pressure-sensitive adhesiveness by ultraviolet rays or heat. The bonding base material may be formed of a thermosetting type or ultraviolet curable type adhesive.

[Manufacturing Method of Base Material for Display Panel]

As long as a target base material for a display panel is obtained, a manufacturing method of the base material for a display panel is not limited. In a preferred embodiment, a manufacturing method of a base material for a display panel, which includes a partition wall separating pixels from each other, includes preparing a transfer film which includes a temporary support and a transfer layer including a photosensitive layer (hereinafter, may be referred to as a “preparing step”), bonding the transfer film to a substrate to arrange the transfer layer and the temporary support in this order on the substrate (hereinafter, may be referred to as a “bonding step”), performing a pattern exposure to the transfer layer (hereinafter, may be referred to as a “exposing step”), and performing a development treatment to the transfer layer to form a pattern constituting the partition wall (hereinafter, may be referred to as a “developing step”). Hereinafter, embodiments of each step will be described.

(Preparing Step)

In the preparing step, a transfer film which includes a temporary support and a transfer layer including a photosensitive layer is prepared. Aspects of the transfer film are described in the section of “Transfer film” described above. The aspect of the transfer film is determined, for example, according to the aspect of a target base material for a display panel (for example, composition, characteristics, and dimensions of the partition wall). The preferred aspect of the transfer film is the same as the preferred aspect of the transfer film described in the section of “Transfer film” described above.

(Bonding Step)

In the bonding step, the transfer film is bonded to a substrate to arrange the transfer layer and the temporary support in this order on the substrate. In a case where the transfer film includes the protective film, the bonding step is performed after the protective film has been peeled off.

Examples of the substrate include a resin substrate, a glass substrate, and a semiconductor substrate. A preferred aspect of the substrate is described, for example, in paragraph [0140] of WO2018/155193A. The contents of the above-described documents are incorporated in the present specification by reference. Examples of a preferred component of the resin substrate include a cycloolefin polymer and polyimides. The thickness of the resin substrate is preferably 5 μm to 200 μm, and more preferably 10 μm to 100 μm.

In the bonding step, a known laminator (for example, a vacuum laminator and an auto-cut laminator) may be used. The bonding step preferably includes pressure-bonding the transfer film to the substrate. Examples of the pressure-bonding method include a known transfer method and laminating method. In the pressure-bonding, it is preferable that pressurization and heating by a roll or the like are performed. The laminating temperature is preferably, for example, 70° C. to 130° C.

(Exposing Step)

In the exposing step, the transfer layer is subjected to a pattern exposure. The “pattern exposure” refers to a form of exposure in a patterned manner, that is, an exposure which forms an exposed portion and an unexposed portion. A positional relationship between the exposed portion and the unexposed portion is determined, for example, according to a shape of a target pattern. The transfer layer may be exposed from the temporary support side or the substrate side.

Examples of a light source used in the exposing step include various lasers, a light emitting diode (LED), an ultra-high pressure mercury lamp, a high pressure mercury lamp, and a metal halide lamp.

Examples of a wavelength of exposure light in the exposing step include 365 nm and 405 nm. A main wavelength of the exposure light is preferably 365 nm. The main wavelength is a wavelength having the highest intensity.

An exposure amount in the exposing step is preferably 5 mJ/cm² to 200 mJ/cm² and more preferably 10 mJ/cm² to 200 mJ/cm².

Preferred aspects of the light source, exposure amount, and exposure method used for the exposure are described, for example, in paragraphs [0146] and [0147] of WO2018/155193A. The contents of the above-described documents are incorporated in the present specification by reference.

(Developing Step)

In the developing step, the transfer layer is subjected to a development treatment to form a pattern constituting the partition wall. In a transfer layer including a positive photosensitive layer, the exposed portion is removed and the unexposed portion forms a pattern, and in a transfer layer including a negative photosensitive layer, the unexposed portion is removed and the exposed portion forms a pattern.

The development treatment is preferably performed using a developer. As the developer, an alkali aqueous solution is preferable. Examples of an alkali compound which can be included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide). Examples of a preferred developer include developers described in paragraph [0194] of WO2015/093271A.

Examples of the development method include methods such as puddle development, shower development, spin development, and dip development. Examples of a preferred development method include development methods described in paragraph [0195] of WO2015/093271A.

(Other Steps)

Depending on the aspect of the target base material for a display panel, the manufacturing method of the base material for a display panel may include other steps. Hereinafter, other exemplary steps are shown. However, the other steps are not limited to the following specific examples.

The manufacturing method of the base material for a display panel may include peeling off the temporary support arranged on the substrate. It is preferable that the temporary support is peeled off between the bonding step and the exposing step, or between the exposing step and the developing step. A peeling method is not limited. For peeling the temporary support, a mechanism similar to peeling mechanism of a cover film, described in paragraphs [0161] and [0162] of JP2010-072589A, may be used.

The manufacturing method of the base material for a display panel may include exposing the pattern. The manufacturing method of the base material for a display panel may include heating the pattern. The manufacturing method of the base material for a display panel may include exposing the pattern and heating the pattern. The heating of the pattern is preferably performed after the exposure of the pattern. The exposure amount is preferably 100 mJ/cm² to 5000 mJ/cm² and more preferably 200 mJ/cm² to 3000 mJ/cm². The heating temperature is preferably 80° C. to 250° C. and more preferably 90° C. to 160° C. The heating time is preferably 1 minute to 180 minutes and more preferably 10 minutes to 60 minutes.

The manufacturing method of the base material for a display panel may include coating at least a part of a surface of the pattern with a light shielding film. A method for forming the light shielding film is not limited. The method for forming the light shielding film may be determined according to the composition and thickness of the light shielding film. Examples of the method for forming the light shielding film include sputtering, vapor deposition, and electroless plating. As necessary, a light shielding film other than the light shielding film which covers the surface of the pattern facing the region for forming the pixels may be removed.

The exemplary manufacturing method of the base material for a display panel is also described in the description of a manufacturing method of a display panel in the following section of “Display panel”. The base material for a display panel may be manufactured based on the above-described matters and matters described in the following section of “Display panel”.

[Application]

Examples of the display panel to which the base material for a display panel is adopted include an LED display panel. The LED display panel may be an LED display panel referred to as a micro LED display panel or a mini LED display panel.

<Display Panel>

Hereinafter, a display panel according to one aspect of the present disclosure will be described.

The display panel includes the base material for a display panel according to the embodiment of the present disclosure. A preferred aspect of the base material for a display panel is the same as the preferred aspect of the base material for a display panel in the section of “Base material for a display panel” described above.

The display panel may include other constituent elements in addition to the base material for a display panel. The other constituent elements may be selected from known constituent elements of a display panel. Examples of the other constituent elements include a wiring board.

The wiring board may be a wiring board included in a known display panel. Examples of the wiring board include a wiring board including substrate and a conductive layer. Examples of the substrate include a resin substrate, a glass substrate, and a semiconductor substrate. Examples of the conductive layer include a metal layer, a conductive metal oxide layer, a graphene layer, a carbon nanotube layer, and a conductive polymer layer. Examples of the wiring board also include a flexible printed circuit board (Flexible Printed Circuits: FPC). The wiring board may be electrically connected to the other constituent elements (for example, the light emitting element).

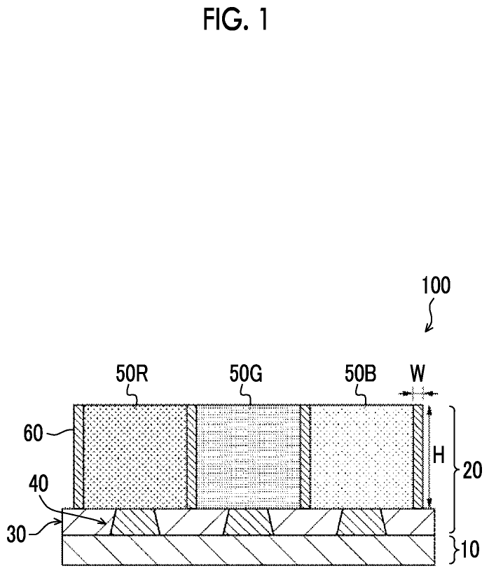

Next, a configuration of the display panel will be described with reference to FIG. 1. FIG. 1 is a schematic enlarged cross-sectional view showing a display panel according to an embodiment. A display panel 100 shown in FIG. 1 includes a wiring board 10 and a base material 20 for a display panel. The base material 20 for a display panel includes a bonding base material 30, a light emitting element 40, a red pixel 50R, a green pixel 50G, a blue pixel 50B, and partition walls 60.

As shown in FIG. 1, the display panel 100 includes the wiring board 10. The wiring board 10 is electrically connected to the light emitting element 40, and transmits a signal for driving the light emitting element 40 to the light emitting element 40.

As shown in FIG. 1, the display panel 100 includes the bonding base material 30. The bonding base material 30 is disposed on the wiring board 10. Specifically, the bonding base material 30 is disposed between the wiring board 10 and the base material 20 for a display panel. The bonding base material 30 improves adhesiveness between the wiring board 10 and the base material 20 for a display panel. For example, the bonding base material 30 is formed by using a thermosetting type or an ultraviolet curable type adhesive.

As shown in FIG. 1, the display panel 100 includes the light emitting element 40. The light emitting element 40 is disposed on the wiring board 10. Specifically, the light emitting element 40 is disposed between the wiring board 10 and the pixels (50R, 50G, and 50B). The light emitting element 40 can emit light toward the pixels (50R, 50G, and 50B). The light emitting element 40 is a light emitting diode (LED). A display panel using the light emitting diode (LED) is called an LED display panel. However, the display panel according to the embodiment of the present disclosure is not limited to the LED display panel.

As shown in FIG. 1, the display panel 100 includes the red pixel 50R, the green pixel 50G, and the blue pixel 50B. The red pixel 50R, the green pixel 50G, and the blue pixel 50B are arranged on the light emitting element 40. Each pixel (50R, 50G, or 50B) is surrounded by the partition walls 60, and the pixels are separated from each other by the partition walls 60. Each pixel (50R, 50G, or 50B) includes a phosphor. Each pixel (50R, 50G, or 50B) functions as the wavelength conversion layer, specifically, the fluorescent light emitting layer. Each pixel (50R, 50G, or 50B) absorbs a part of the light emitted from the light emitting element 40 and emits fluorescence.

As shown in FIG. 1, the display panel 100 includes the partition walls 60. The partition wall 60 is disposed between two adjacent pixels, and separates the pixels. The partition wall 60 is the composition including an organic resin. The softening temperature of the partition wall 60 is adjusted to 300° C. or higher. The cross-sectional shape of the partition wall 60 is rectangular. The aspect ratio of the partition wall 60 is represented by a ratio of a height H of the partition wall 60 to a width W of the partition wall 60. At least a part of the surface of the partition wall 60 is coated with a light shielding film (not shown). Specifically, the light shielding film (not shown) covers side surfaces of the partition wall 60, that is, surfaces facing the pixels.

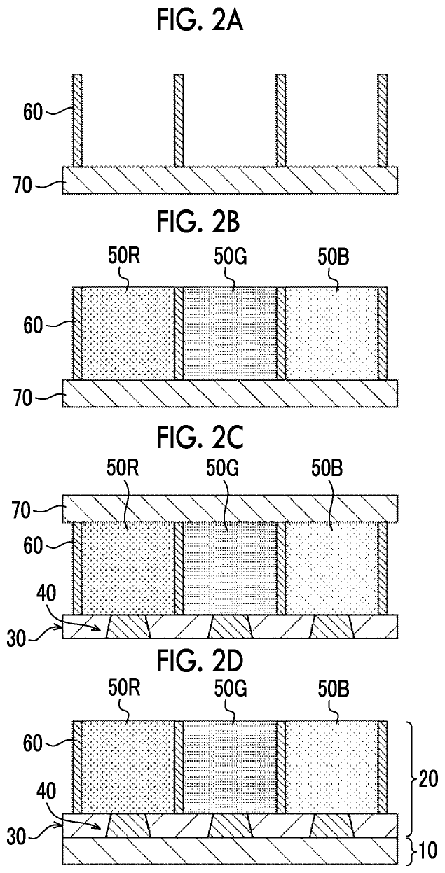

Next, a manufacturing method of the display panel will be described with reference to FIGS. 2A to 2D. FIGS. 2A to 2D are schematic enlarged cross-sectional views showing a manufacturing method of the display panel shown in FIG. 1.

As shown in FIG. 2A, the partition walls 60 are formed on the substrate 70. The partition walls 60 are formed on the substrate 70 by photolithography using a transfer film. Specifically, a transfer film which includes a temporary support and a transfer layer including a photosensitive layer is bonded to the substrate 70 to arrange the transfer layer and the temporary support on the substrate 70. As described in the section of “Base material for a display panel” described above, a pattern constituting the partition wall 60 is formed through exposure and development of the photosensitive layer arranged on the substrate 70. In FIG. 2A, by forming a light shielding film on the partition wall 60, a light shielding film which covers at least a part of the surface of the partition wall 60 can be formed. In the process of forming the light shielding film, as necessary, a light shielding film other than the light shielding film which covers the surface of the partition wall 60 facing a space for forming pixels may be removed.

As shown in FIG. 2B, the red pixel 50R, the green pixel 50G, or the blue pixel 50B is formed in each region defined by the partition wall. For example, the red pixel 50R is formed by applying, exposing, developing, and heating a composition including a red phosphor. For example, the green pixel 50G is formed by applying, exposing, developing, and heating a composition including a green phosphor. For example, the blue pixel 50B is formed by applying, exposing, developing, and heating a composition including a blue phosphor.

As shown in FIG. 2C, the laminate obtained in the step shown in FIG. 2B is bonded to the bonding base material 30 including the light emitting element 40. An adhesive may be applied to the bonding base material 30 before the laminate is bonded to the bonding base material 30 including the light emitting element 40. The bonding base material 30 and the light emitting element 40 are arranged on another substrate (not shown). Another substrate (not shown) is removed before the base material 20 for a display panel is bonded to the wiring board 10 described later.

As shown in FIG. 2D, the base material 20 for a display panel is formed by removing the substrate 70, and the base material 20 for a display panel is bonded to the wiring board 10 to obtain the display panel 100.

As described above, FIGS. 2A to 2D show a method of manufacturing the display panel 100 by bonding each pixel (50R, 50G, or 50B) and the partition walls 60 to the bonding base material 30 including the light emitting element 40. However, the display panel 100 may be manufactured by forming the partition walls 60 on the bonding base material 30 including the light emitting element 40 by photolithography using a transfer film, and then forming each pixel (50R, 50G, or 50B) by the method described above. In addition, the display panel 100 may be manufactured by arranging the partition walls 60 previously formed by photolithography using a transfer film on the bonding base material 30 including the light emitting element 40, and then forming each pixel (50R, 50G, or 50B) by the method described above.

### EXAMPLES

Hereinafter, the present disclosure will be described in detail according to Examples. However, the present disclosure is not limited to the following Examples. The matters shown in the following Examples (for example, materials, amounts used, proportions, treatment contents, and treatment procedures) may be changed as appropriate within a range not departing from the gist of the present disclosure.

<Production of Photosensitive Composition>

A photosensitive composition having a composition shown in Table 1 was prepared. In Table 1, the content of each component is represented by parts by mass.

TABLE 1

| | | Photosensitive composition | | | | |
|---|---|---|---|---|---|---|
| | | 1 | 2 | 3 | 4 | 5 |
| Binder polymer | A-1 | 53.3 | — | 53.3 | 53.3 | — |
| | A-2 | — | — | — | — | 53.3 |
| | A-3 | — | 53.3 | — | — | — |
| Polymerizable | B-1 | — | — | 17.6 | — | 19.5 |
| compound | B-2 | — | — | 17.5 | — | — |
| | B-3 | — | — | 3.9 | — | 19.5 |
| | B-4 | 24 | 24 | — | 24 | — |
| | B-5 | 11 | 11 | — | 11 | — |
| | B-6 | 4 | 4 | — | 4 | — |
| Polymerization | B-CIM | 6.8 | 6.8 | 6.8 | 6.8 | 6.8 |
| initiator | (manufactured by Hampford Research Inc.) | | | | | |
| Sensitizer | SB-PI 701 | 0.075 | 0.075 | 0.075 | 0.13 | 0.075 |
| | (manufactured by SANYO TRADING CO., LTD.) | | | | | |
| Chain transfer | Leucocrystal Violet | — | — | 0.035 | — | 0.035 |
| agent | (manufactured by Tokyo Chemical Industry Co., Ltd.) | | | | | |
| | N-Phenylcarbamoylmethyl-N-carboxymethylaniline | 0.135 | 0.135 | 0.1 | 0.11 | 0.1 |
| | (manufactured by FUJIFILM Wako Pure Chemical | | | | | |
| | Corporation) | | | | | |
| Polymerization | TDP-G | 0.26 | 0.26 | 0.26 | 0.25 | 0.26 |
| inhibitor | (manufactured by Kawaguchi Chemical Industry Co., LTD.) | | | | | |
| Rust inhibitor | CBT-1 | 0.12 | 0.12 | 0.12 | 0.1 | 0.12 |
| | (manufactured by Johoku Chemical Industry Co., Ltd.) | | | | | |
| Antioxidant | 4-Hydroxymethyl-4-methyl-1-phenyl-3-pyrazolidone | 0.01 | 0.01 | 0.01 | 0.01 | 0.01 |
| | (manufactured by FUJIFILM Wako Pure Chemical | | | | | |
| | Corporation) | | | | | |
| Surfactant | F-552 | 0.3 | 0.3 | 0.3 | 0.3 | 0.3 |
| | (manufactured by DIC Corporation) | | | | | |

Details of the binder polymers shown in Table 1 are shown in Table 2.

TABLE 2

| Binder polymer | | A-1 | A-2 | A-3 |
|---|---|---|---|---|
| Constitutional unit | MAA | 20 | 29 | 20 |
| | St | 46 | 52 | — |
| | MMA | 2 | 19 | 2 |
| | BzMA | — | — | 46 |
| | GMA-MMA | 32 | — | 32 |

| | | | |
|---|---|---|---|
| Tg [° C.] | 86 | 131 | 65 |

The following abbreviations shown in Table 2 have the following meanings, respectively.
“MAA”: methacrylic acid
“St”: styrene
“MMA” methyl methacrylate
“BzMA”: benzyl methacrylate
“GMA-MMA”: constitutional unit obtained by adding glycidyl methacrylate to a constitutional unit derived from methyl methacrylate
“Tg”: glass transition temperature

Details of the polymerizable compounds shown in Table 1 are shown in Table 3.

TABLE 3
Polymerizable compound

| | |
|---|---|
| B-1 | BPE-500 |
| | (manufactured by Shin-Nakamura Chemical Co., Ltd.) |
| B-2 | BPE-100 |
| | (manufactured by Shin-Nakamura Chemical Co., Ltd.) |
| B-3 | ARONIX M-510 |
| | (manufactured by Toagosei Co., Ltd.) |
| B-4 | A-NOD-N |
| | (1,9-nonanediol diacrylate, manufactured by Shin-Nakamura |
| | Chemical Co., Ltd.) |
| B-5 | KAYARAD DPHA |
| | (dipentaerythritol hexaacrylate, manufactured by Nippon |
| | Kayaku Co., Ltd.) |
| B-6 | ARONIX TO-2349 |
| | (monomer having carboxy group, manufactured by |
| | Toagosei Co., Ltd.) |

### Example 1

[Manufacturing of Transfer Film]

As a temporary support, a polyethylene terephthalate film (LUMIRROR 16KS40, manufactured by Toray Industries, Inc., thickness: 16 μm) was prepared. A photosensitive composition 1 was applied to the temporary support, and dried at 120° C. for 3 minutes to form a photosensitive layer. As a protective film, a polyethylene terephthalate film (LUMIRROR 16KS40, manufactured by Toray Industries, Inc., thickness: 16 μm) was pressure-bonded to the photosensitive layer. By the above procedure, a transfer film including the temporary support, the photosensitive layer, and the protective film in this order was obtained. The photosensitive layer is a negative photosensitive layer, and a thickness of the photosensitive layer was 20 μm.

[Manufacturing Base Material for Display Panel and Display Panel]

As a substrate, glass (manufactured by Corning Incorporated, EAGLE XG, thickness: 0.7 mm) was prepared. After peeling off the protective film from the transfer film, the transfer film was bonded to the substrate under the following laminating conditions. The obtained laminate included the substrate, the photosensitive layer, and the temporary support in this order.
Rubber roller temperature: 80° C.
Linear pressure: 100 N/cm
Transportation speed: 2.0 m/min

The photosensitive layer was subjected to a pattern exposure through the temporary support. In the pattern exposure, using a proximity type exposure machine (manufactured by Hitachi High-Tech Electronics Engineering Co., Ltd.) including an ultra-high pressure mercury lamp and using a photo mask, the photosensitive layer was exposed with an exposure amount of 140 mJ/cm² (i-rays). The photo mask includes a light transmissive pattern for forming a pattern constituting the partition wall. A line width of the light transmissive pattern formed on the photo mask was set in a range of 1 μm to 10 μm in 1 μm increments.

After the temporary support was peeled off from the laminate, the photosensitive layer was subjected to a development treatment. Specifically, the photosensitive layer was developed for 100 seconds using a 1% by mass sodium carbonate aqueous solution (liquid temperature: 25° C.) as a developer. Moisture was removed by blowing air on the pattern obtained by the development.

The pattern was subjected to a heat treatment at 200° C. for 20 minutes. A partition wall was formed by the above procedure (see, for example, FIG. 2A). The pattern constituting the partition wall formed an opening in a plan view.

A light shielding film was formed on the partition wall by sputtering. The light shielding film was a thin film of aluminum. A thickness of the light shielding film was 50 nm. A light shielding film other than the light shielding film covering the surface of the partition wall facing a space for forming pixels was removed by a laser.

The space (that is, the opening) defined by the partition wall was filled with a resist material including a red phosphor (Lumidot 610, manufactured by Sigma-Aldrich Co., LLC), and then exposed, developed, and heated to for a red pixel (see, for example, FIG. 2B). In the same way, a green pixel was formed by using a resist material including a green phosphor (Lumidot 530, manufactured by Sigma-Aldrich Co., LLC), and then a blue pixel was formed by using a resist material including a blue phosphor (Lumidot 480, manufactured by Sigma-Aldrich Co., LLC) (see, for example, FIG. 2B). By the above method, each pixel of red pixel, green pixel, and blue pixel was formed. Each pixel was surrounded by the partition wall, and the pixels were separated from each other by the partition wall.

A material (specifically, an ultraviolet curable adhesive) for a bonding base material was applied to a sapphire substrate on which a light emitting diode was disposed as a light emitting element. A part of the light emitting element was exposed by removing the material for the bonding base material, which covered the light emitting element. A quartz glass substrate was bonded to the light emitting element and the bonding base material. The material for the bonding base material was cured by irradiation with ultraviolet rays to improve adhesiveness between the light emitting element and the bonding base material. The sapphire substrate was peeled off by laser lift-off to obtain a bonding base material including the light emitting element. The light emitting element and the bonding base material were arranged on the quartz glass. On the quartz glass, an outer circumference of the light emitting element was surrounded by the bonding base material.

The partition walls and the pixels arranged on the substrate were bonded to the bonding base material which included the light emitting element and disposed on the quartz glass. The quartz glass substrate and the substrate were peeled off from the obtained laminate by laser lift-off to obtain a base material for a display panel (see, for example, FIGS. 2C and 2D).

A display panel was obtained by bonding the base material for a display panel to the wiring board (see, for example, FIG. 2D).

### Examples 2, 3, and 6 and Comparative Example 1

A transfer film, a base material for a display panel, and a display panel were obtained by the same method as in Example 1, except that the type of photosensitive composition was changed according to the description in Table 4.

### Example 4

A transfer film, a base material for a display panel, and a display panel were obtained by the same method as in Example 1, except that the thickness of the photosensitive layer was changed to 30 μm.

### Example 5

A transfer film, a base material for a display panel, and a display panel were obtained by the same method as in Example 1, except that the thickness of the photosensitive layer was changed to 10 μm.

<Evaluation: Resolution>

A cross section of the pattern (that is, the partition wall) formed by using the transfer film was observed with an electron microscope. The width and height of the appropriate partition wall with the minimum width were measured and the aspect ratio of the partition wall was determined. The appearance partition wall means a partition wall having a width comparable to the design value and having no appearance defects. Resolution was evaluated according to the following standard based on a width W and an aspect ratio R of the partition wall. The measurement results and evaluation results are shown in Table 4.

[Evaluation Standard of Resolution: Width W]
A: 1 μm≤W≤4 μm
B: 4 μm<W≤10 μm

[Evaluation Standard of Resolution: Aspect Ratio R]
A: 5≤R
B: 1≤R<5
C: R<1

<Evaluation: Collapse and Deformation>

The partition wall of the base material for a display panel was observed from an overhead view with an electron microscope, and collapse and deformation were evaluated according to the following standard. The evaluation results are shown in Table 4.
A: partition wall was not collapsed, and the partition wall was not meandered.
B: partition wall was not collapsed, and a part of the partition wall was meandered.
C: partition wall was collapsed, and the entire partition wall was meandered.

TABLE 4

| | Photosensitive layer | | | | | | |
|---|---|---|---|---|---|---|---|
| | | Transmittance at | Softening | Partition wall | | | |
| | | photosensitive | temperature | | | | Softening |
| | Photosensitive | wavelength | after exposure | Width | Height | Height/width | temperature |
| | composition | [%] | [° C.] | [μm] | [μm] | (aspect ratio) | [° C.] |
| Example 1 | 1 | 50.4 | 400 | 3 | 20 | 6.7 | 400 |
| Example 2 | 2 | 51.2 | 350 | 3 | 20 | 6.7 | 350 |
| Example 3 | 3 | 49.3 | 300 | 3 | 20 | 6.7 | 300 |
| Example 4 | 1 | 33.6 | 400 | 8 | 30 | 3.8 | 400 |
| Example 5 | 1 | 72.3 | 400 | 3 | 10 | 3.3 | 400 |
| Example 6 | 4 | 17.1 | 360 | 8 | 20 | 2.5 | 360 |
| Comparative | 5 | 49.1 | 250 | 5 | 20 | 4 | 250 |
| Example 1 | | | | | | | |

| | Partition wall | | | | | | |
|---|---|---|---|---|---|---|---|
| | | Double | Solubility | | Evaluation | | |
| | Elastic | bond | in | | Resolution | | |
| | modulus | value | PGMEA | Optical | | Aspect | Collapse and |
| | [GPa] | [mmol/g] | [g/L] | density | Width | ratio | deformation |
| Example 1 | 5.5 | 0.4 | 0.01 | 3.8 | A | A | A |
| Example 2 | 5.3 | 0.5 | 0.02 | 3.8 | A | A | A |
| Example 3 | 5 | 0.7 | 0.05 | 3.8 | A | A | B |
| Example 4 | 5.5 | 0.8 | 0.1 | 3.8 | B | B | B |
| Example 5 | 5.5 | 0.3 | 0.01 | 3.8 | A | B | A |
| Example 6 | 5.1 | 1.2 | 0.5 | 3.8 | B | B | B |
| Comparative | 4.5 | 1 | 0.8 | 3.8 | B | B | C |
| Example 1 | | | | | | | |

In Table 4, a value listed in the column of “Transmittance at photosensitive wavelength” indicates a transmittance at a wavelength of 365 nm. In Table 4, a value listed in the column of “Softening temperature after exposure” indicates a softening temperature of the photosensitive layer exposed by light having a wavelength of 365 nm. The softening temperature shown in Table 4 was measured with AFM5100N type SPM manufactured by Hitachi High-Tech Science Corporation and a local thermal analysis system nano-TA manufactured by U.S. Analysis Instruments Corporation according to the method described above. The elastic modulus shown in Table 4 was measured with AFM Dimension Icon manufactured by Bruker Corporation according to the method described above. The matters relating to the calibration of the AFM probe used for measuring the elastic modulus were as follows. A warping sensitivity was calculated to be 66.74 nm/V from an inclination of a force curve by measuring a force curve of a quartz substrate in advance. A spring constant was calculated by measuring a thermal fluctuation of the probe. Specifically, the spring constant was calculated to be 1.828 N/m with the Thermal Tune method included in the software of AFM manufactured by Bruker Corporation. A curvature of a tip is calculated to be 9.2 nm by measuring a shape of a sample for calibrating tip curvature (RM-12M: Ti Roughness Sample) and using an image analysis mode (Tip Qualification) included in the software of AFM manufactured by Bruker Corporation.

With regard to the transfer film, in Table 4, it is shown that, in a case where the transmittance of the photosensitive layer at the photosensitive wavelength is high, it is possible to form a fine pattern by improving the resolution. In addition, in Table 4, it is shown that, in a case where the transmittance of the photosensitive layer at the photosensitive wavelength is high, it is possible to form a pattern having a high aspect ratio by improving the resolution. Further, in Table 4, it is shown that, in a case where the softening temperature of the photosensitive layer after exposure is high, the softening temperature of the formed pattern is high.

With regard to the base material for a display panel including the partition wall separating the pixels, in Table 4, it is shown that, in a case where the softening temperature of the partition wall is 300° C. or higher, the collapse and deformation of the partition wall are reduced.

### EXPLANATION OF REFERENCES

10: wiring board
20: base material for display panel
30: bonding base material
40: light emitting element
50R: red pixel
50G: green pixel
50B: blue pixel
60: partition wall
70: substrate
H: height of partition wall
W: width of partition wall
100: display panel

What is claimed is:

1. A base material for a display panel, comprising:
a partition wall separating pixels,
wherein the partition wall is a composition including an organic resin,
a width of the partition wall is 1 μm or more,
a ratio of a height of the partition wall to the width of the partition wall is 1 or more, and
a softening temperature of the partition wall is 300° C. or higher.

2. The base material for a display panel according to claim 1,
wherein an elastic modulus of the partition wall is 4 GPa or more.

3. The base material for a display panel according to claim 1,
wherein an elastic modulus of the partition wall is 5 GPa or more.

4. The base material for a display panel according to claim 1,
wherein a double bond value of the partition wall is 2.0 mmol/g or less.

5. The base material for a display panel according to claim 1,
wherein a double bond value of the partition wall is 0.08 mmol/g or less.

6. The base material for a display panel according to claim 1,
wherein a double bond value of the partition wall is 0.01 mmol/g or more.

7. The base material for a display panel according to claim 1,
wherein a solubility of the partition wall in propylene glycol monomethyl ether acetate is 0.1 g/L or less.

8. The base material for a display panel according to claim 1,
wherein a solubility of the partition wall in propylene glycol monomethyl ether acetate is 0.05 g/L or less.

9. The base material for a display panel according to claim 1,
wherein the composition includes a compound having at least one polymerizable group selected from the group consisting of a vinyl group, an acryloyl group, a methacryloyl group, a styryl group, and a maleimide group.

10. The base material for a display panel according to claim 1, further comprising:
a light shielding film with which at least a part of a surface of the partition wall is coated.

11. The base material for a display panel according to claim 10,
wherein a thickness of the light shielding film is 50 nm or more.

12. The base material for a display panel according to claim 10,
wherein the light shielding film includes a metal, and a thickness of the light shielding film is 10 nm or more and 200 nm or less.

13. A display panel comprising:
the base material for a display panel according to claim 1.
